(19) United States
(12) Patent Application Publication
(10) Pub. No.: US 2010/0124610 A1
(43) Pub. Date: May 20, 2010

(54) SUBSTRATE POSITION DETECTION APPARATUS, SUBSTRATE POSITION DETECTION METHOD, FILM DEPOSITION APPARATUS, FILM DEPOSITION METHOD, AND A COMPUTER READABLE STORAGE MEDIUM

(75) Inventors: KATSUYOSHI AIKAWA, Oshu-shi (JP); MANABU HONMA, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/617,908

(22) Filed: Nov. 13, 2009

(30) Foreign Application Priority Data
Nov. 19, 2008 (JP) 2008-295641
May 29, 2009 (JP) 2009-130532

(51) Int. Cl. C23C 16/00; G01B 11/14; G01B 11/00; B05C 11/10

(52) U.S. Cl. 427/255.28; 356/620; 356/615; 118/712

(57) ABSTRACT

A disclosed substrate position detection apparatus includes an imaging portion configured to take an image of a substrate subject to a position detection; a panel member provided between the imaging portion and the substrate and including a first opening that ensures a field of view for the imaging portion with respect to the substrate, the panel member having a light scattering property; a first illuminating portion configured to illuminate the panel member; and a processing portion capable of determining a position of the substrate in accordance with the image taken through the first opening by the imaging portion.

### CROSS-REFERENCE TO RELATED APPLICATION

This application claims the benefit of priority of Japanese Patent Applications No. 2008-295641 and No. 2009-130532, filed on Nov. 19, 2008 and May 29, 2009, respectively, with the Japanese Patent Office, the entire contents of which are hereby incorporated by reference.

### BACKGROUND OF THE INVENTION

1. Field of the Invention

The present invention relates to a substrate position detection apparatus and a substrate position detection method that detect a position of a substrate housed in a semiconductor device fabrication apparatus; a film deposition apparatus provided with the substrate position detection apparatus; a film deposition method performed using the film deposition apparatus; a computer readable storage medium storing a computer program for causing the substrate position detection apparatus to perform the substrate position detection method; and a computer readable storage medium storing a computer program for causing the film deposition apparatus to perform the film deposition method.

2. Description of the Related Art

In a semiconductor device fabrication process, a substrate is transferred into various fabrication apparatuses including a film deposition apparatus, an etching apparatus, an inspection apparatus and the like, and undergoes corresponding processes. Specifically, the substrate is transferred into the fabrication apparatuses by a transfer arm having a fork or an end effector. The substrate transferred by the transfer arm has to be accurately positioned in a predetermined position. For example, when the substrate is deviated from the predetermined position, the substrate cannot be uniformly heated, thereby degrading uniformity in film thickness and/or film properties. In addition, such deviation may cause a problem in that the substrate cannot be taken away by the fork or an end effector.

Moreover, among some molecular layer deposition (MLD) apparatuses, which have attracted much attention because of its thickness controllability and uniformity, there is an MLD apparatus where a substrate is rotated at relatively high speed so that reaction gases are alternately adsorbed, instead of alternately supplying the reaction gases. In such an apparatus, the substrate may be ejected by the rotation if the substrate is not in a predetermined place.

In order to solve such problems by accurately arranging the substrates in predetermined positions, there is proposed a method in which plural laser sensors or photoelectronic sensors are provided to detect positional deviations of the substrates (see Patent Document 1), and a method in which a contact type sensor is provided to detect positional deviations of the substrates (see Patent Document 2).

However, in the case of the laser sensors, a large number of the laser sensors are required in a fabrication apparatus in which plural substrates are housed, because plural laser sensors are used with respect to one substrate, which increases a cost of the apparatus. In addition, another laser sensor for detecting a position of a susceptor with respect to the substrate is required, which increases the cost. Moreover, when plural laser sensors are used, there is caused a problem in that an optical system may become complicated. On the other hand, when the substrate is heated, the contact type sensor cannot be used.

In order to detect a position of a substrate, there is a method that employs a charge-coupled device (COD) to take an image of the substrate, and thus the position is detected in accordance with the image (see Patent document 3). According to this method, an image of the substrate and the susceptor can be taken by only one COD camera, so that an unnecessary increase in the cost may be avoided and the optical system may be simplified. In addition, because the CCD camera remotely takes an image of the substrate and the susceptor, the CCD camera can be used regardless of whether the substrate is heated.

Patent document 1: Japanese Patent Application Laid-Open Publication No. 2001-007009.

Patent document 2: Japanese Patent Application Laid-Open Publication No. 2007-142086.

Patent document 3: Japanese Patent Application Laid-Open Publication No. 2001-117064.

### SUMMARY OF THE INVENTION

However, as a result of an investigation carried out by the inventors of the present invention, it has been revealed that detection errors may be caused by reflection of light when an image of a substrate is taken by a camera, and thus a position of the substrate is not accurately detected.

The present invention has been made in view of the above, and provides a substrate position detection apparatus and a substrate position detection method that are capable of reducing detection errors in a substrate position detection through taking an image of a substrate; a film deposition apparatus provided with the substrate position detection apparatus; a film deposition method using the film deposition apparatus; a computer readable storage medium storing a computer program for causing the substrate position detection apparatus to perform the substrate position detection method; and a computer readable storage medium storing a computer program for causing the film deposition apparatus to perform the film deposition method.

A first aspect of the present invention provides a substrate position detection apparatus. The substrate position detection apparatus includes an imaging portion configured to take an image of a substrate subject to a position detection; a panel member provided between the imaging portion and the substrate and including a first opening that ensures a field of view for the imaging portion with respect to the substrate, the panel member having a light scattering property; a first illuminating portion configured to illuminate the panel member; and a processing portion capable of determining a position of the substrate in accordance with the image taken through the first opening by the imaging portion.

A second aspect of the present invention provides a substrate position detection method comprising steps of placing a substrate subject to a position detection in a substrate receiving portion of a susceptor; illuminating a panel member provided above the substrate and including a first opening, the panel member having a light scattering property; taking an image of an area including the substrate and the substrate receiving portion through the first opening; estimating a position of the substrate receiving portion in accordance with the image of the area; estimating a position of the substrate in accordance with the image of the area; and determining whether the substrate is in a predetermined position from the positions of the substrate and the substrate receiving portion.

A third aspect of the present invention provides a film deposition apparatus for depositing a film on a substrate by carrying out a cycle of alternately supplying at least two kinds of reaction gases that react with each other to the substrate to produce a layer of a reaction product in a chamber. The film deposition apparatus includes a susceptor rotatably provided in the chamber; a substrate receiving portion that is provided in one surface of the susceptor and the substrate is placed in; a substrate position detection apparatus according to the first aspect for detecting a position of the substrate placed in the substrate receiving portion; a first reaction gas supplying portion configured to supply a first reaction gas to the one surface; a second reaction gas supplying portion configured to supply a second reaction gas to the one surface, the second reaction gas supplying portion being separated from the first reaction gas supplying portion along a rotation direction of the susceptor; a separation area located along the rotation direction between a first process area in which the first reaction gas is supplied and a second process area in which the second reaction gas is supplied; a center area that is located substantially in a center portion of the chamber in order to separate the first process area and the second process area, and has an ejection hole that ejects a first separation gas along the one surface; and an evacuation opening provided in the chamber in order to evacuate the chamber. The separation area includes a separation gas supplying portion that supplies a second separation gas, and a ceiling surface that creates in relation to the one surface of the susceptor a thin space in which the second separation gas may flow from the separation area to the process area side in relation to the rotation direction.

A fourth aspect of the present invention provides a film deposition method for depositing a film on a substrate, using the film deposition apparatus according to the third aspect. The film deposition method includes steps of placing the substrate on a substrate receiving portion provided in one surface of a susceptor rotatably provided in the chamber; illuminating a panel member provided above the substrate and including a first opening, the panel member having a light scattering property; taking an image of an area including the substrate and the substrate receiving portion through the first opening; estimating a position of the substrate receiving portion in accordance with the image of the area; estimating a position of the substrate in accordance with the image of the area; determining whether the substrate is in a predetermined position from the positions of the substrate and the substrate receiving portion; rotating the susceptor on which the substrate is placed, when it is determined that the substrate is in the predetermined position in the step of determining; supplying a first reaction gas from a first reaction gas supplying portion to the susceptor; supplying a second reaction gas from a second reaction gas supplying portion to the susceptor, the second reaction gas supplying portion being separated from the first reaction gas supplying portion along a rotation direction of the susceptor; supplying a first separation gas from a separation gas supplying portion provided in a separation area located between a first process area in which the first reaction gas is supplied from the first reaction gas supplying portion and a second process area in which the second reaction gas is supplied from the second reaction gas supplying portion, in order to flow the first separation gas from the separation area to the process area relative to the rotation direction of the susceptor in a thin space created between a ceiling surface of the separation area and the susceptor; supplying a second separation gas from an ejection hole formed in a center area located in a center portion of the chamber; and evacuating the chamber.

A fifth aspect of the present invention provides a computer readable storage medium storing a program for causing the substrate position detection apparatus according to the first aspect to perform a substrate position detection method including steps of placing a substrate subject to a position detection in a substrate receiving portion of a susceptor; illuminating a panel member provided above the substrate and including a first opening, the panel member having a light scattering property; taking an image of an area including the substrate and the substrate receiving portion through the first opening; estimating a position of the substrate receiving portion in accordance with the image of the area; estimating a position of the substrate in accordance with the image of the area; and determining whether the substrate is in a predetermined position from the positions of the substrate and the substrate receiving portion.

A sixth aspect of the present invention provides a computer readable storage medium storing a program for causing the film deposition apparatus according to the third aspect to perform a film deposition method. This film deposition method includes steps of placing the substrate on a substrate receiving portion provided in one surface of a susceptor rotatably provided in the chamber; illuminating a panel member provided above the substrate and including a first opening, the panel member having a light scattering property; taking an image of an area including the substrate and the substrate receiving portion through the first opening; estimating a position of the substrate receiving portion in accordance with the image of the area; estimating a position of the substrate in accordance with the image of the area; determining whether the substrate is in a predetermined position from the positions of the substrate and the substrate receiving portion; rotating the susceptor on which the substrate is placed, when it is determined that the substrate is in the predetermined position in the step of determining; supplying a first reaction gas from a first reaction gas supplying portion to the susceptor; supplying a second reaction gas from a second reaction gas supplying portion to the susceptor, the second reaction gas supplying portion being separated from the first reaction gas supplying portion along a rotation direction of the susceptor; supplying a first separation gas from a separation gas supplying portion provided in a separation area located between a first process area in which the first reaction gas is supplied from the first reaction gas supplying portion and a second process area in which the second reaction gas is supplied from the second reaction gas supplying portion, in order to flow the first separation gas from the separation area to the process area relative to the rotation direction of the susceptor in a thin space created between a ceiling surface of the separation area and the susceptor; supplying a second separation gas from an ejection hole formed in a center area located in a center portion of the chamber; and evacuating the chamber.

### BRIEF DESCRIPTION OF THE DRAWINGS

FIG. 1 schematically illustrates a substrate position detection apparatus according to an embodiment of the present invention;

FIG. 2 is a flowchart illustrating a substrate position detection method according to an embodiment of the present invention;

FIG. 3 is an explanatory view for explaining a substrate layout in a film deposition apparatus in which the substrate position detection apparatus according to the embodiment of the present invention is employed;

FIG. 4 illustrates an image taken by the substrate position detection apparatus according to the embodiment of the present invention (a subsection (b)), in contrast with another image taken by a substrate position detection apparatus configured for comparison (a subsection (a));

FIG. 5 is an explanatory view for explaining how to estimate the center position of a substrate in the substrate position detection apparatus and method according to an embodiment of the present invention;

FIG. 6 schematically illustrates a substrate position detection apparatus according to another embodiment of the present invention;

FIG. 7 schematically illustrates a film deposition apparatus equipped with the substrate position detection apparatus of FIG. 1;

FIG. 8 is a perspective view illustrating an inner configuration of the film deposition apparatus of FIG. 7;

FIG. 9 is a plan view illustrating an inner configuration of the film deposition apparatus of FIG. 7;

FIG. 10 illustrates a spatial relationship among a gas supplying nozzle, a susceptor, and a convex portion of the film deposition apparatus of FIG. 7;

FIG. 11 is a partial cross-sectional view of the film deposition apparatus of FIG. 7;

FIG. 12 is a broken perspective view of the film deposition apparatus of FIG. 7;

FIG. 13 is a partial cross-sectional view illustrating a flow of a purge gas;

FIG. 14 is a perspective view illustrating a transfer arm entering an inside of a chamber of the film deposition apparatus of FIG. 7;

FIG. 15 is a plan view illustrating a gas flow pattern of gases flowing in the chamber of the film deposition apparatus of FIG. 7;

FIG. 16 is an explanatory view for explaining a shape of the convex portion of the film deposition apparatus of FIG. 7;

FIG. 17 illustrates a modification example of the gas supplying nozzle of the film deposition apparatus of FIG. 7;

FIG. 18 illustrates modification examples of the convex portion of the film deposition apparatus of FIG. 7;

FIG. 19 illustrates modification examples of the convex portion with the gas supplying portion of the film deposition apparatus of FIG. 7;

FIG. 20 illustrates another modification example of the convex portion of the film deposition apparatus of FIG. 7;

FIG. 21 illustrates a modification example of a gas supplying nozzle layout in the film deposition apparatus of FIG. 7;

FIG. 22 illustrates yet another modification example of the convex portion of the film deposition apparatus of FIG. 7;

FIG. 23 illustrates an example where the convex portion is provided for a reaction gas supplying nozzle of the film deposition apparatus of FIG. 7;

FIG. 24 illustrates another modification example of the convex portion of the film deposition apparatus of FIG. 7;

FIG. 25 schematically illustrates a film deposition apparatus equipped with the substrate position detection apparatus of FIG. 1, according to an embodiment of the present invention;

FIG. 26 schematically illustrates a substrate processing apparatus including the film deposition apparatus of FIGS. 7 and 25;

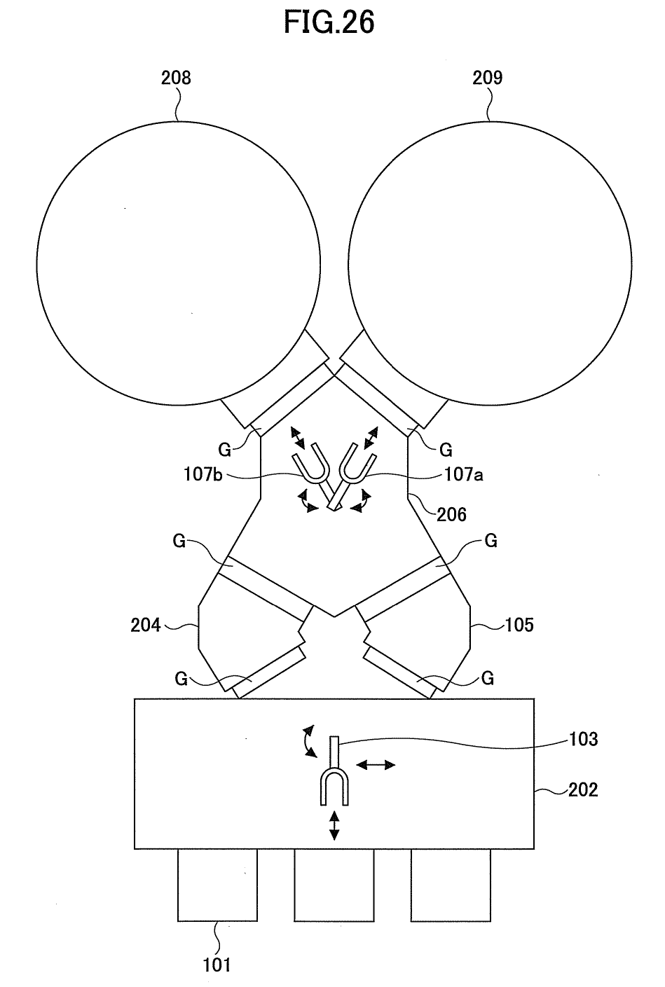

FIG. 27 is an explanatory view for explaining a substrate position detection apparatus according to another embodiment of the present invention;

FIG. 28 is a flowchart illustrating a substrate position detection method according to another embodiment of the present invention; and

FIG. 29 is an explanatory view for explaining the substrate position detection method according to another embodiment of the present invention.

### DETAILED DESCRIPTION OF THE PREFERRED EMBODIMENT

According to an embodiment of the present invention, there are provided a substrate position detection apparatus and a substrate position detection method that are capable of reducing detection errors in a substrate position detection through taking an image of a substrate; a film deposition apparatus provided with the substrate position detection apparatus; a film deposition method using the film deposition apparatus; a computer readable storage medium storing a computer program for causing the substrate position detection apparatus to perform the substrate position detection method; and a computer readable storage medium storing a computer program for causing the film deposition apparatus to perform the film deposition method.

Non-limiting, exemplary embodiments of the present invention will now be described with reference to the accompanying drawings. In the drawings, the same or corresponding reference symbols are given to the same or corresponding members or components. It is to be noted that the drawings are illustrative of the invention, and there is no intention to indicate scale or relative proportions among the members or components. Therefore, the specific thickness or size should be determined by a person having ordinary skill in the art in view of the following non-limiting embodiments.

### (Substrate Position Detection Apparatus)

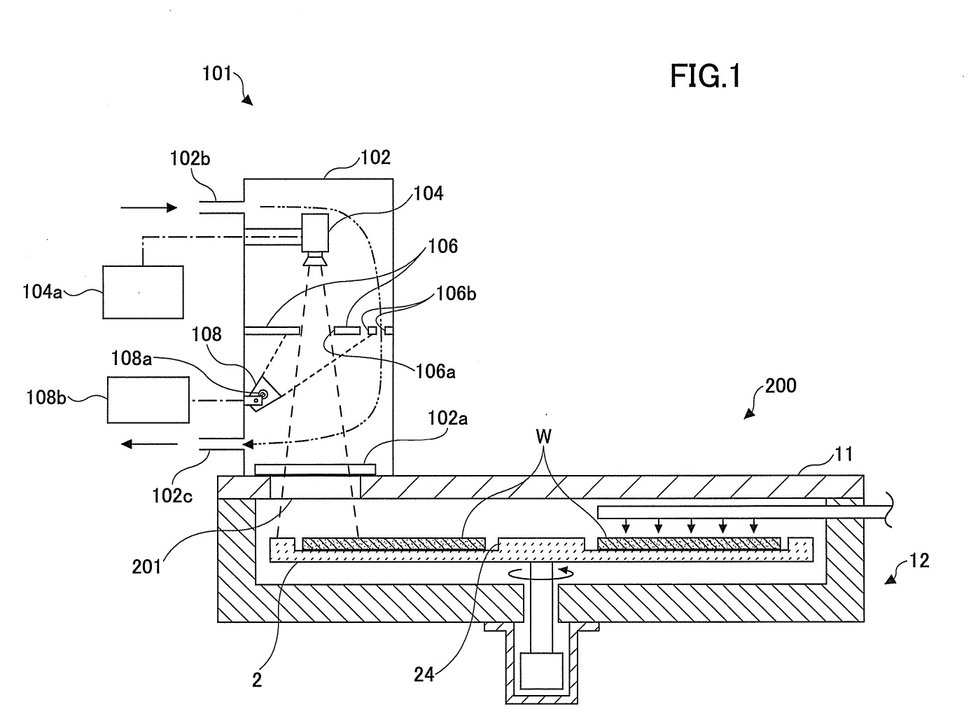

FIG. 1 is a schematic view illustrating a substrate position detection apparatus according to an embodiment of the present invention. As shown, a substrate position detection apparatus 101 according to this embodiment includes a chassis 102, a camera 104 provided inside the chassis 102 to take an image of a wafer W subject to the position detection, a panel 106 arranged below the camera 104 in the chassis 102, and a light source 108 configured to illuminate the panel 106.

The chassis 102 is placed on a film deposition apparatus 200 in which the wafer W subject to the position detection by the substrate position detection apparatus 101 is housed. The chassis 102 has an opening at a bottom portion thereof, and the opening is covered by a transparent window 102a. In addition, a pipe 102b is connected to an upper side portion of the chassis 102, and a pipe 102c is connected to a lower side portion of the chassis 102. As shown by a two-dot chain arrow in FIG. 1, clean air, for example, is supplied to the chassis 102 from the pipe 102b and evacuated from the pipe 102c, which may cool the camera 104. In addition, when detecting a position of the wafer W, if the wafer W is heated in the film deposition apparatus 200, the window 102a is heated by heat radiation from the wafer W and a susceptor on which the substrate is placed, and thus heat haze is caused, which may blur the image of the wafer W. However, the cleaned air flowing downward in the chassis 102 can cool the window 102a, thereby reducing the blurring of the image.

The camera 104 includes a charge-coupled device (CCD) as an imaging device, and is attached on the inner upper portion of the chassis 102 to face the opening and the window 102a. With this configuration, the camera 104 can take an image of the wafer W placed on the susceptor 2 in the film deposition apparatus 200 through the window 102a and a viewport hermetically provided in a ceiling plate 11 of the film deposition apparatus 200.

In addition, a control portion 104a is electrically connected to the camera 104. The control portion 104a controls operations (on/off, focusing, image-taking, and the like) of the camera 104, and processes image data obtained by the camera 104. Such processes may include an arithmetic processing for specifying the position of the wafer W from the image data. Additionally, the control portion 104a may download a program stored in a storage medium through an input/output (I/O) device (not shown), and carries out a substrate position detection method described below by controlling the camera 104, the light source 108, and the like in accordance with the program.

The panel 106 is made of an acrylic plate painted with white pigment and thus has a milky white color, in this embodiment, and attached between the camera 104 and the window 102a in the chassis 102. An opening 106a is formed in substantially a center of the panel 106, through which the camera 104 can take an image of the wafer W and an area around the wafer W in the film deposition apparatus 200. A dimension and position of the opening 106a may be determined so that the camera 104 can take an image of the wafer W and the area around the wafer W, specifically, an edge of the wafer W for use in the position detection and a position detection mark 2a formed in the susceptor 2 (described later). In addition, the dimension and position of the opening 106a may be determined taking into consideration a distance between the panel 106 and the camera 104.

Moreover, the panel 106 has one or more openings 106b in an area that does not obstruct the image taking of the wafer W and the like by the camera 104. The opening 106b is provided in order to facilitate the cleaned air supplied from the pipe 102b connected to the chassis 102 to flow through an inside space of the chassis 102.

The light source 108 is attached in an inner side wall of the chassis 102 between the panel 106 and the window 102a, in this embodiment. The light source 108 can illuminate a lower surface of the panel 106, but does not illuminate the camera 104 through the opening 106a of the panel. The light source 108 may vertically swivel, and preferably have a motor or the like to change illumination directions, upward or downward. With this, the light source 108 can illuminate alternately the panel 106 above the light source 108 or the wafer W below the light source 108.

The light source 108 includes a white light emitting diode (LED) 108a, and is provided with an electric source 108b to supply electricity to the white LED. The electric source 108b can change its output voltage, so that illumination intensity of the wafer W illuminated indirectly by the panel 106 can be adjusted, which makes it possible for the camera 104 to take a distinct image.

Advantages and effects of the substrate position detection apparatus 101 so configured, according to this embodiment of the present invention, will be apparent from the following explanation about a substrate position detection method.

### (Substrate Position Detection Method)

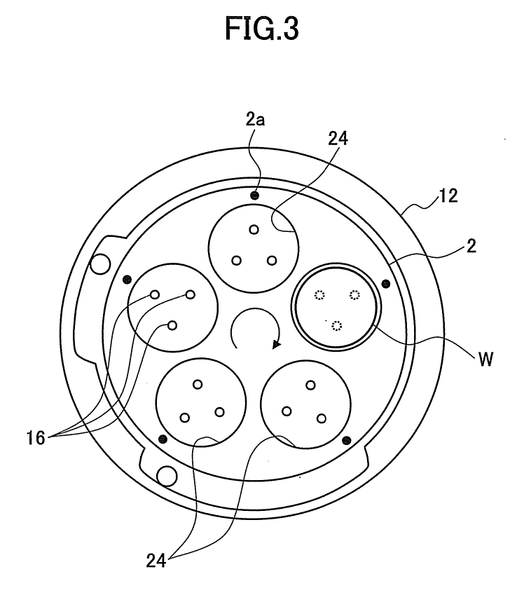

A substrate position detection method according to an embodiment of the present invention is explained with reference to FIGS. 1 through 5. Here, the substrate position detection method is carried out, in this embodiment, to detect a position of the wafer W in the film deposition apparatus 200 using the substrate position detection apparatus 101. Incidentally, the susceptor 2 used in the film deposition apparatus 200 has five substrate receiving portions 24 on which five wafers are placed, respectively, at equal angular intervals (about 72°), as shown in FIG. 3. The wafer position detection is carried out when the wafer is transferred into the film deposition apparatus 200 and placed in a predetermined one of the substrate receiving portions 24, sequentially for the five wafers (or less) transferred per one run. In addition, the substrate receiving portion 24 may have a circular concave portion having an inner diameter larger than a diameter of the wafer W. Specifically, the inner diameter of the concave substrate receiving portion 24 may be about 304 mm through about 308 mm with respect to the wafer having a diameter of about 300 mm (12 inch).

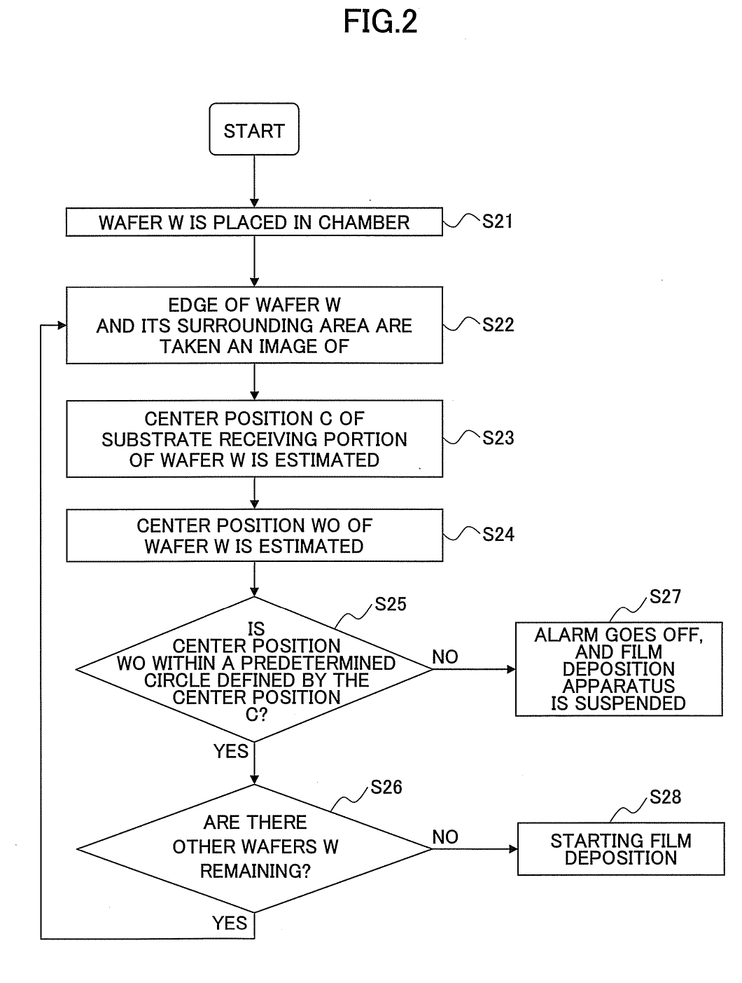

First, in Step S21 (FIG. 2), the wafer W is transferred into a vacuum chamber 12 (FIG. 1) of the film deposition apparatus 200, and placed on the susceptor 2 by lift pins 16 (FIG. 3) that are elevatable through through-holes provided in the susceptor 2. Next, the wafer W is moved by rotation of the susceptor 2 to a position (referred to as an imaging position, below) where an image of the wafer W can be taken by the camera 104 of the substrate position detection apparatus 101.

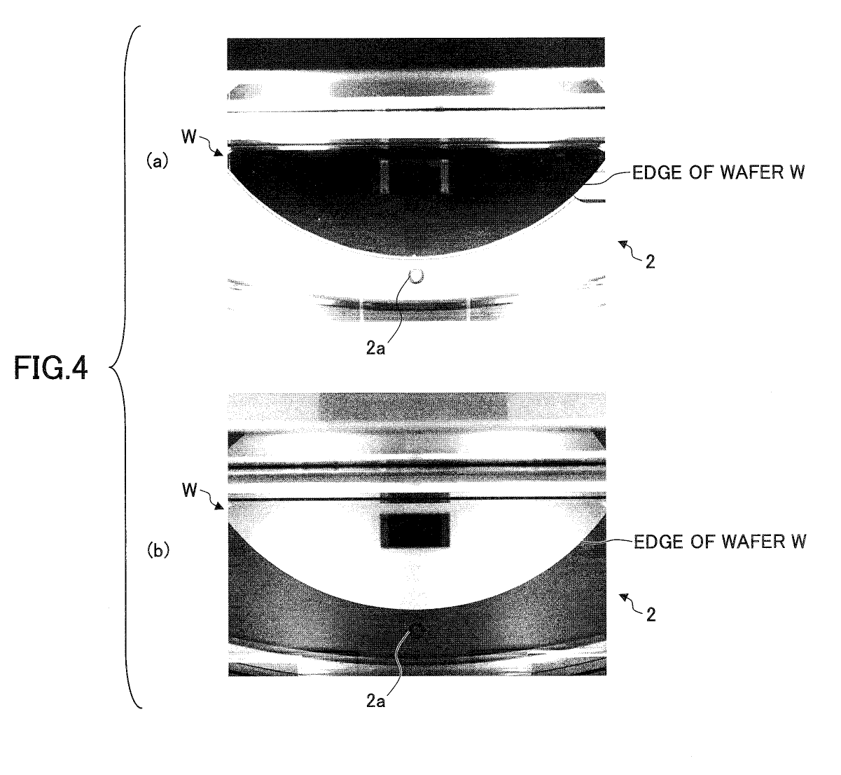

The light source 108 of the substrate position detection apparatus 101 is turned on to illuminate the lower surface of the panel 106. Then, an image of an area including the edge of the wafer W and its surrounding area is taken by the camera 104 of the substrate position detection apparatus 101 (Step S22), and image data obtained by the camera 104 are collected by the control portion 104a. An example of the image taken by the camera 104 is illustrated in a subsection (b) of FIG. 4. As shown, the wafer W appears substantially uniform and entirely white, while the susceptor 2 appears black. A black rectangle in the white area (the wafer W) is the opening 106b of the panel 106, reflected by a mirror surface of the wafer W.

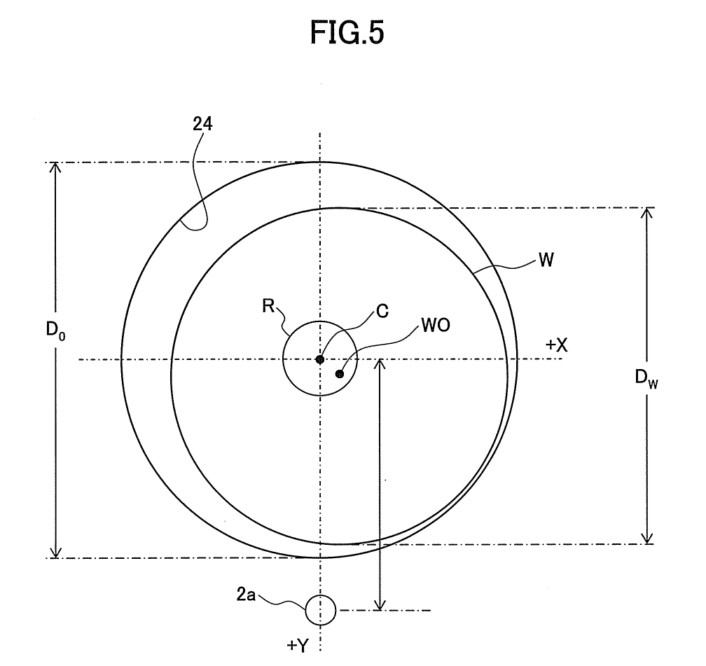

Subsequently, the position detection mark 2a formed in the susceptor 2 of the film deposition apparatus 200 is detected by the control portion 104a. This detection may be carried out through an image processing in accordance with a shape, a pattern or the like of the position detection mark 2a, which are stored in advance in the control portion 104a. Then, a center position of the susceptor 2 on which the wafer W is placed is estimated in accordance with the position of the position detection mark 2a (Step S23). For this estimation, a center of the position detection mark 2a and a center C of the substrate receiving portion 24 are preferably aligned along a predetermined axis, as shown in FIG. 5. With this, the center C of the substrate receiving portion 24 can be easily estimated from a distance from the position detection mark 2a, the distance having been determined in advance.

Next, an edge line of the wafer W is recognized from the image taken by the camera 104 by the control portion 104a. This recognition may be carried out using an edge recognition function provided in advance in the control portion 104a. Subsequently, a point (in coordinate) at which plural lines (normal lines) that intersect corresponding tangential lines of the edge line at the tangent sites at an right angle converge is obtained. This converging point is an estimated wafer center WO of the wafer W (Step S24).

Then, a distance d between the estimated wafer center WO of the wafer W and the center C of the substrate receiving portion 24 is obtained. Here, the following expression is satisfied when the center C of the substrate receiving portion 24 is expressed as a coordinate point (Xc, Yc) and the wafer center WO of the wafer C is expressed as a coordinate point (Kw, Yw) in a coordinate shown in FIG. 5:

d²=((Xw−Xc)²+(Yw−Yc)²)/CF (1)

where CF is a conversion factor expressing a ratio between an actual length and a distance between pixels of the CCD.

Next, it is determined using the distance d obtained in accordance with the expression (1) whether the wafer W is within a predetermined area (Step S25). For example, when the substrate receiving portion 24 is a circular concave shape having an inner diameter of D0 mm while the wafer W has a diameter of Dw mm, and if the following expressions:

0≦d²≦L² (2)

L=(D₀−D_{w})/2 (3)

are satisfied, the wafer center WO of the wafer W is positioned within a circle R that is defined by the center C of the substrate receiving portion 24 and has a radius of L. Namely, in this case, the wafer W is within the substrate receiving portion 24, and thus it is determined that the wafer W is within the predetermined range.

Incidentally, when the wafer W is placed using a transfer arm having an end effector, rather than lift pins, the following expressions may be used to determine whether the wafer W is within a predetermined range.

0≦d²≦L₁² (4)

L₁²<L=(D₀−D_{w})/2 (5)

In addition, while the processes such as the above image taking, the estimation of the center, and the determination on whether the wafer W is within a predetermined range are carried out, the next wafer W is placed in another substrate receiving portion 24 adjacent to the substrate receiving portion 24 where the wafer W on which such processes are carried out in the film deposition apparatus 200. With this, the wafer transfer and the position detection of the wafer W can be carried out without wasting time, thereby preventing a reduction of throughput.

When the distance d is within the predetermined range (Step S25: YES), the control portion 104a inquires of the film deposition apparatus 200 if the wafer transfer is completed (Step S26). When the control portion 104a obtains information indicating that there are wafers to be processed (Step S26: YES), the procedure returns to Step S22. Namely, the susceptor 2 of the film deposition apparatus 200 is rotated, so that the next wafer W moves to the detection position. An image of an edge of the wafer W and its surrounding area are taken, and the steps up to Step S25 are carried out with respect to the next wafer W. Subsequently, the steps S21 through S25 are repeated in the same manner until the position detection is carried out with respect to all the wafers W on the susceptor 2.

When it is determined that the distance d is not within the predetermined range (Step S25: NO), the control portion 104a emits an alarm and sends to the film deposition apparatus 200 a signal requesting suspension of the film deposition apparatus 200 (Step S27), which brings the film deposition apparatus 200 into an idle state. In this case, an operator of the film deposition apparatus 200 manually carries out recovery operations for placing the wafer W that the control portion 104a determines not to be within the predetermined range into the predetermined position in accordance with predetermined manual procedures.

When it is determined that no wafers remain, namely, all the wafers W (five wafers W) are determined to be in the predetermined position (Step S26: NO), a film is deposited on the wafers W in the film deposition apparatus 200 (Step S28). After the film deposition is completed, the wafers W are transferred out from the vacuum chamber 12 of the film deposition apparatus 200. However, before transferring out the wafers W, the position detection for the wafers W may be carried out in accordance with the steps S21 through S27. The wafer position detection after the film deposition may be effective when the wafers are shifted during the film deposition due to the rotation of the susceptor 2 whereby the transfer arm having the end effector cannot grab the wafers W, for example.

In the following, advantages and effects of the substrate position detection method according to this embodiment are explained with reference to subsections (a) and (b) of FIG. 4. The subsection (a) of FIG. 4 illustrates an image taken by a camera while directly illuminating the wafer W and its surrounding area of the susceptor 2, for comparison. As shown, because the wafer W appears black in this case, when shade caused by an inner circumferential wall of the substrate receiving portion 24 of the susceptor 2, and/or shade caused by the wafer W are interposed with the edge of the wafer W, the wafer edge cannot be accurately detected. As a result, the center of the wafer W and thus the wafer position cannot be accurately detected, either. In addition, because the very edge of the wafer W is inclined outward, relatively intense reflection light may be caused from the edge. In this case, the edge of the wafer W appears intensely bright, and thus an arc shape of the edge may be distorted, which leads to inaccurate recognition of the wafer edge and thus the center WO of the wafer W.

On the other hand, according to the substrate position detection method of this embodiment, using the substrate position detection apparatus 101, the wafer W appears uniformly white as shown in the subsection (b) of FIG. 4. This is because the panel 106 is made of an acrylic plate painted with white pigment and has a milky white color in the substrate position detection apparatus 101. Namely, when the light source 108 illuminates the lower surface (facing the wafer W) of the panel 106, the panel 106 emanates white light substantially entirely and uniformly. In this case, because the wafer W below the panel 106 is illuminated by the emanating panel 106 (or such a panel 106 is reflected by the mirror surface of the wafer W), the wafer W appears entirely and uniformly white. Therefore, the wafer W appears white, including the edge, in the image taken by the camera 104. On the contrary, the susceptor 2 on which the wafer W is placed is usually made of carbon or silicon carbide (SiC), and thus appears black even when the susceptor 2 is illuminated by the panel 106 emanating white light. Therefore, relatively strong contrast is caused between the wafer W and the susceptor 2 in the image, which contributes to accurate edge recognition and thus the estimation of the wafer center WO of the wafer W. In addition, because the light from the panel 106 reaches the wafer W and the susceptor 2 from every direction, shade is less likely to be caused by the wafer W and the substrate receiving portion 24 of the susceptor 2. As a whole, the edge of the wafer W is clearly recognized, thereby reducing detection errors.

Moreover, because the panel 106 emanates entirely and uniformly, the intense reflection is not caused from the edge of the wafer W, thereby reducing detection errors caused by such reflection. Furthermore, because no intense reflection is caused from the mirror surface of the wafer W, an optical flare is not created in the camera 104, thereby enabling accurate recognition of the edge of the wafer W.

From the foregoing, the advantages and effects of the substrate position detection apparatus and the substrate position detection method according to the embodiment of the present invention are understood.

(A Film Deposition Apparatus Provided with the Substrate Position Detection Apparatus)

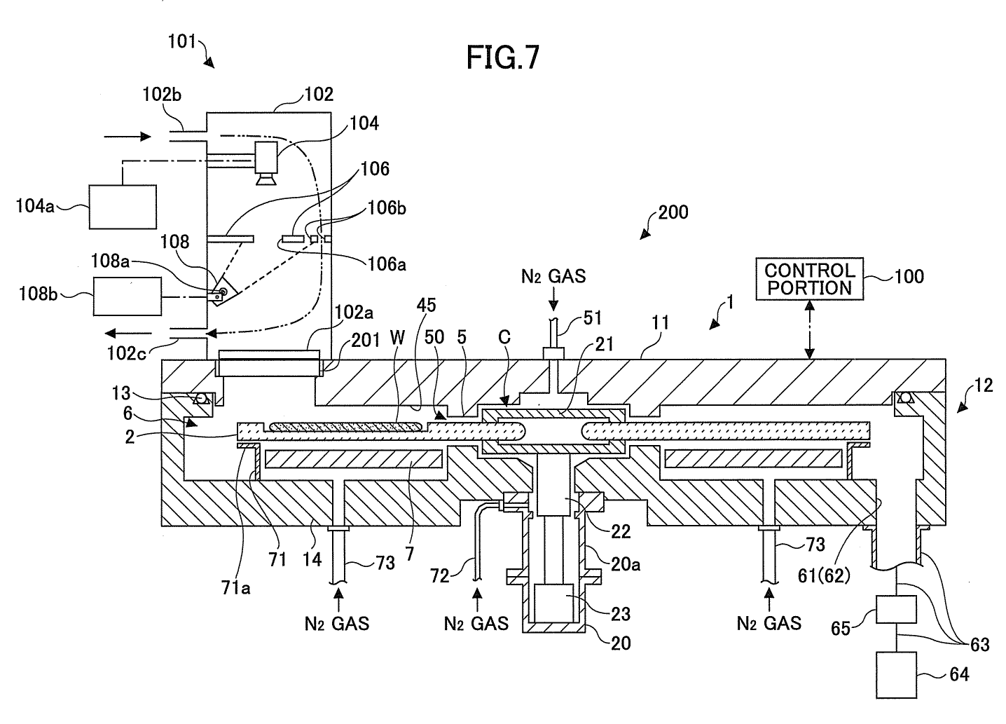

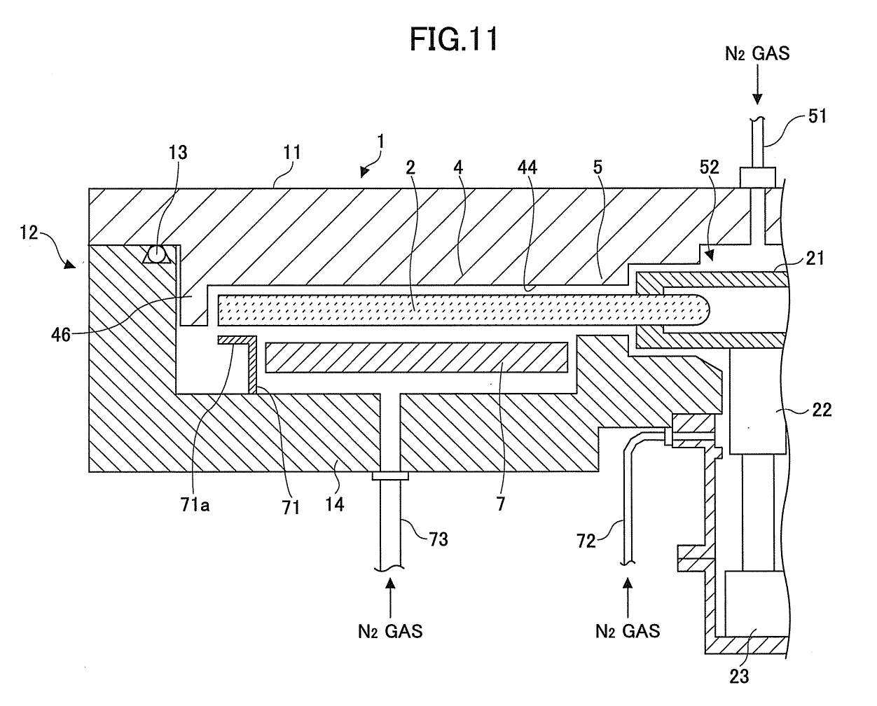

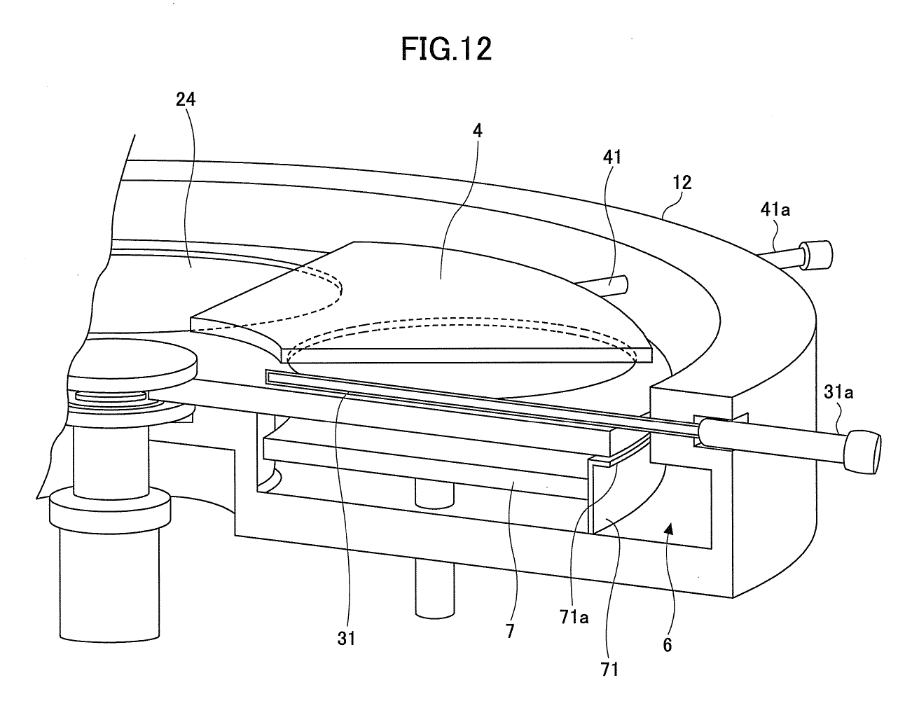

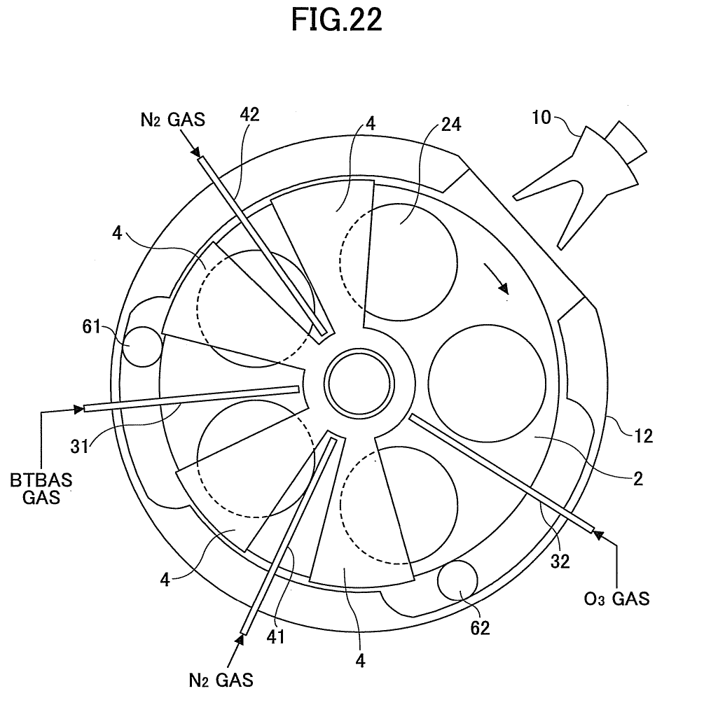

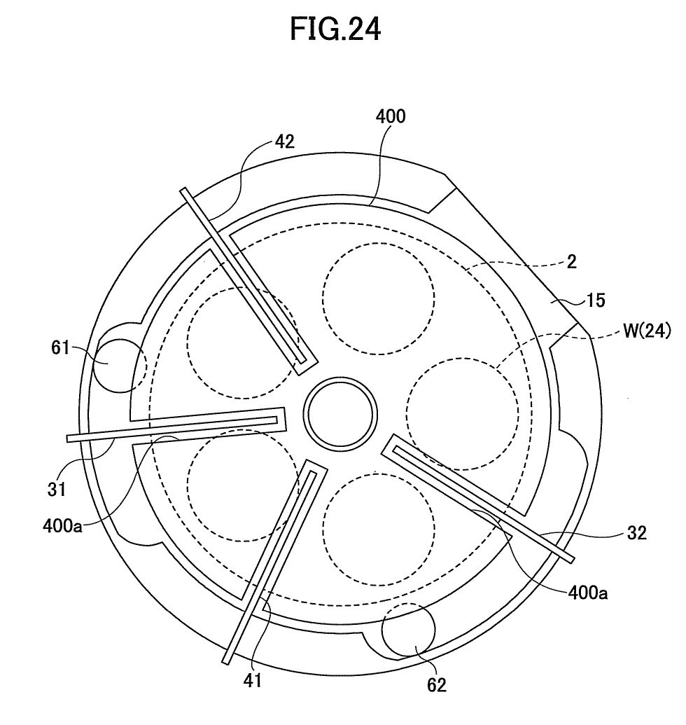

Next, a film deposition apparatus provided with the substrate position detection apparatus, according to an embodiment of the present invention, is explained with reference to FIGS. 7 through 25.

A film deposition apparatus 200 according to an embodiment of the present invention has a vacuum chamber 1 having a flattened cylinder shape, and a susceptor 2 that is located inside the vacuum chamber 1 and has a rotation center at a center of the vacuum chamber 1. The vacuum chamber 1 is made so that a ceiling plate 11 can be separated from a chamber body 12. The ceiling plate 11 is pressed onto the chamber body 12 via a sealing member 13 such as an O ring, so that the vacuum chamber 1 is hermetically sealed. On the other hand, the ceiling plate 11 can be raised by a driving mechanism (not shown) when the ceiling plate 11 has to be removed from the chamber body 12.

In addition, a viewport 201 made of, for example, quartz is hermetically provided in the ceiling plate 11 via a sealing member such as an O ring (not shown). The substrate position detection apparatus 101 is attached on the upper surface of the ceiling plate 11 so that the window 102a of the substrate position detection apparatus 101 faces the viewport 201. The substrate position detection apparatus 101 is configured as explained above, and thus repetitive explanation is omitted. Use of the substrate position detection apparatus 101 makes it possible to carry out the substrate position detection method to detect a position of the wafer W (FIG. 7) on the susceptor 2 of the film deposition apparatus 200.

As shown in FIG. 7, the susceptor 2 is supported at the center by a core portion 21, which is fixed on a top end of a rotational shaft 22 that extends in a vertical direction. The rotational shaft 22 penetrates a bottom portion 14 of the chamber body 12 and is fixed at the lower end to a driving mechanism 23 that can rotate the rotational shaft 22 clock wise around a vertical axis in this embodiment. The rotational shaft 22 and the driving mechanism 23 are housed in a case body 20 having a cylinder with a bottom. The case body 20 is hermetically fixed to a lower surface of the bottom portion 14 via a flanged pipe portion 20a, which isolates an inner environment of the case body 20 from an outer environment.

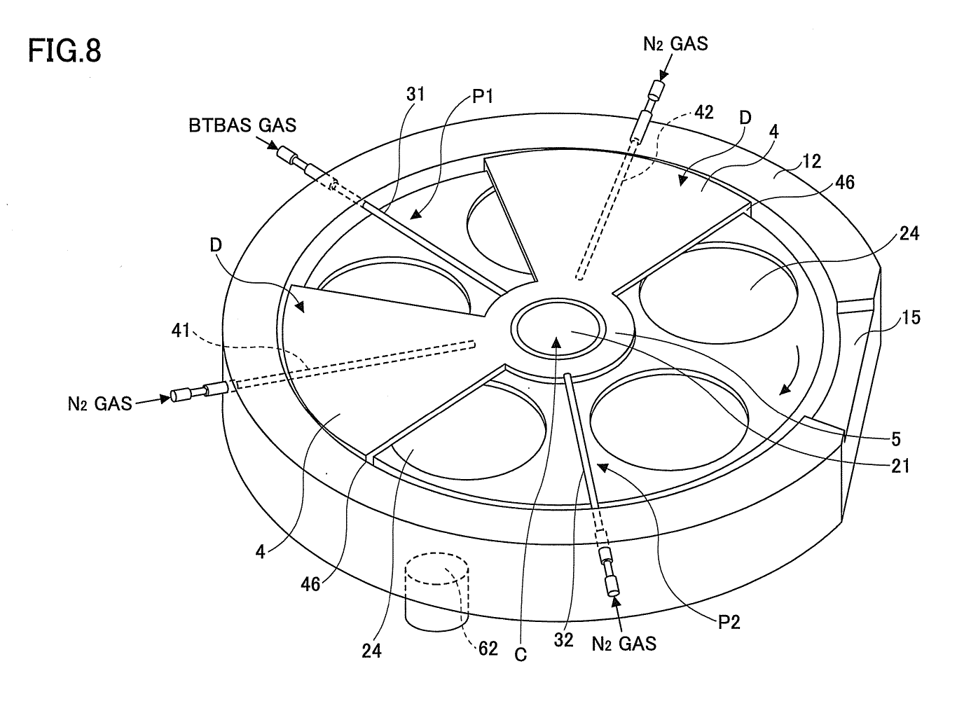

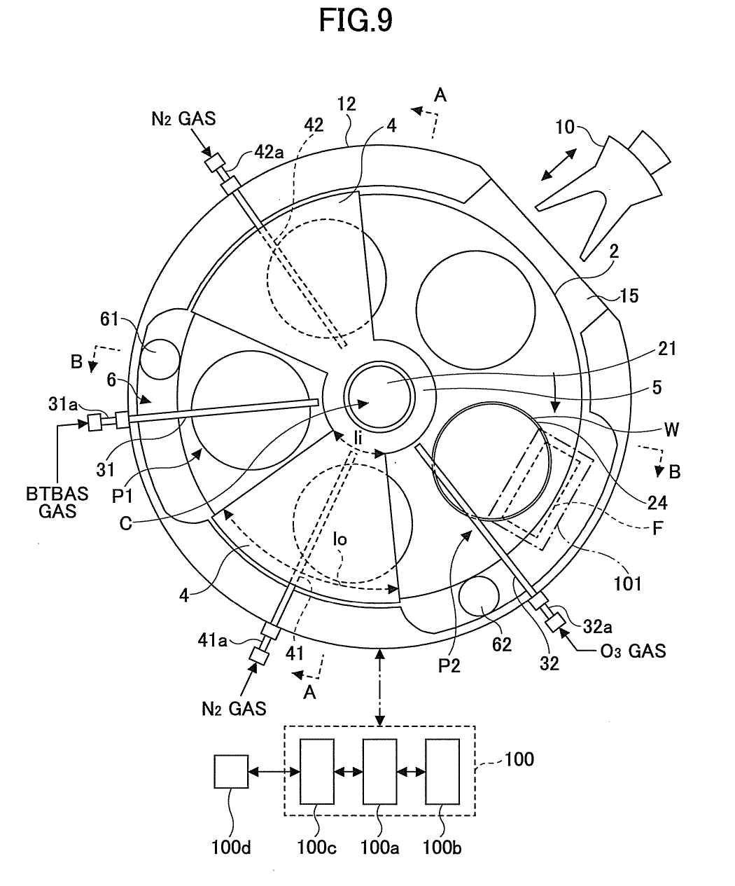

As shown in FIGS. 8 and 9, plural (five in the illustrated example) substrate receiving portions 24 having a circular concave shape, each of which receives a wafer W, are formed in an upper surface of the susceptor 2, although only one wafer W is illustrated in FIG. 3. The substrate receiving portions 24 are arranged at equal angular intervals of about 72°.

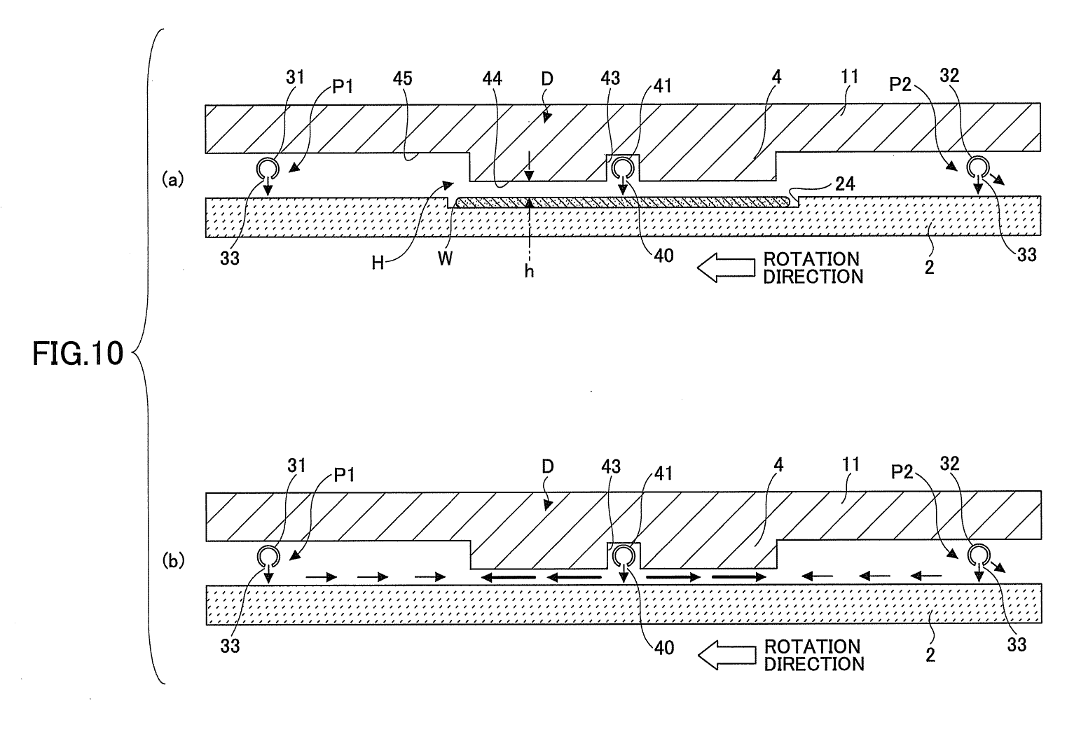

Referring to a subsection (a) of FIG. 10, the substrate receiving portion 24 and the wafer W placed in the substrate receiving portion 24 are illustrated. As shown in this drawing, the substrate receiving portion 24 has a diameter slightly larger, for example, by 4 mm than the diameter of the wafer W and a depth equal to a thickness of the wafer W. Therefore, when the wafer W is placed in the substrate receiving portion 24, a surface of the wafer W is at the same elevation of a surface of an area of the susceptor 2, the area excluding the substrate receiving portions 24. If there is a relatively large step between the area and the wafer W, gas flow turbulence is caused by the step, which may affect thickness uniformity across the wafer W. This is why the two surfaces are at the same elevation. While “the same elevation” may mean here that a height difference is less than or equal to about 5 mm, the difference has to be as close to zero as possible to the extent allowed by machining accuracy.

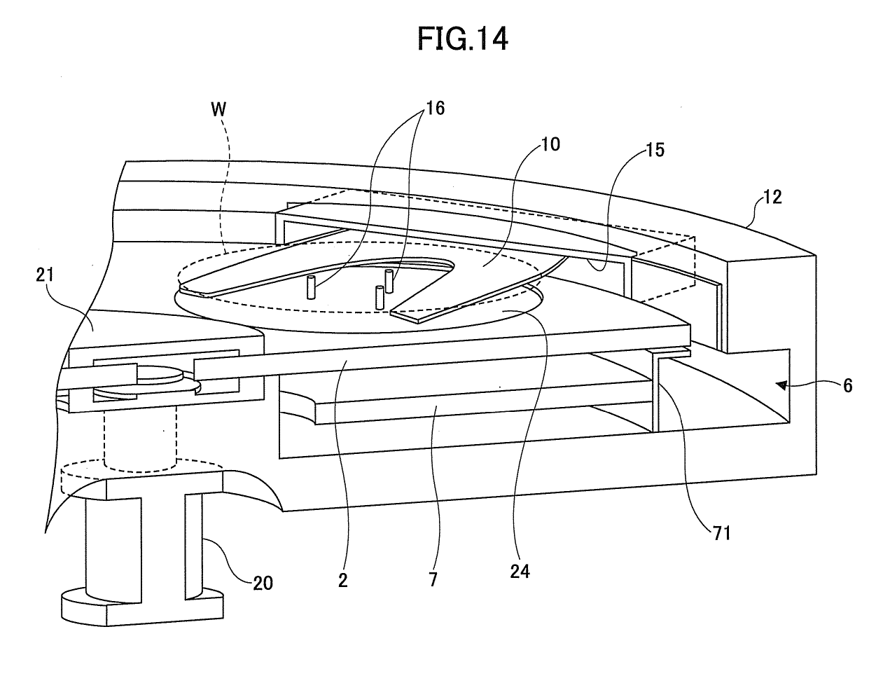

In the bottom of the substrate receiving portion 24, there are formed three through-holes (not shown) through which three corresponding lift pins 16 (see FIG. 14) are raised/lowered. The lift pins 16 support a lower surface of the wafer W and raises/lowers the wafer W.

A transfer opening 15 is formed in a side wall of the chamber body 12 as shown in FIGS. 8, 9 and 14. Through the transfer opening 15, the wafer W is transferred into or out from the vacuum chamber 1 by a transfer arm 10 (FIG. 9). The transfer opening 15 is provided with a gate valve (not shown) by which the transfer opening 15 is opened or closed. When the substrate receiving portion 24 of the susceptor 2 is in alignment with the transfer opening 15 and the gate valve is opened, the wafer W is transferred into the vacuum chamber 1 and placed in the substrate receiving portion 24 as a substrate receiving portion of the susceptor 2 from the transfer arm 10. In order to lower/raise the wafer W into/from the substrate receiving portion 24, there are provided lift pins 16 that are raised or lowered through corresponding through-holes formed in the substrate receiving portion 24 of the susceptor 2 by an elevation mechanism (not shown).

Next, a two-dimensional positional relationship among the substrate position detection apparatus 101, the susceptor 2, the substrate receiving portion 24, and the transfer opening 15 is explained. As shown in FIG. 9, the substrate position detection apparatus 101 is arranged about 72° away from a center of the transfer opening 15. With this, when one of the five substrate receiving portions 24 is aligned with the transfer opening 15, the substrate position detection apparatus 101 is positioned above the adjacent substrate receiving portion 24. Therefore, the edge of the wafer W and its surrounding area in the adjacent substrate receiving portion 24 can exist in a field of view F of the camera 104 (FIG. 9), and thus it can be determined whether the wafer W is positioned in the predetermined position, while another wafer W is transferred to the substrate receiving portion 24 aligned with the transfer opening 15. Namely, while the position detection is carried out on one wafer W in one substrate receiving portion 24, another wafer W can be transferred to another substrate receiving portion 24. In such a manner, five wafers W are sequentially placed in the substrate receiving portions 24, and the position detection is carried out with respect to all the wafers W, thereby preventing a reduction of throughput that may be caused when accompanied by the position detection.

Referring again to FIGS. 8 and 9, a first reaction gas nozzle 31, a second reaction gas nozzle 32, and separation gas nozzles 41, 42 are provided above the susceptor 2. These gas nozzles 31, 32, 41, 42 extend in radial directions and at predetermined angular intervals. With this configuration, the substrate receiving portion 24 can move through and below the gas nozzles 31, 32, 41, and 42. In the illustrated example, the second reaction gas nozzle 32, the separation gas nozzle 41, the first reaction gas nozzle 31, and the separation gas nozzle 42 are arranged clockwise in this order. These gas nozzles 31, 32, 41, and 42 penetrate the circumferential wall portion of the chamber body 12 and are supported by attaching their base ends, which are gas inlet ports 31a, 32a, 41a, 42a, respectively, on the outer circumference of the wall portion. Although the gas nozzles 31, 32, 41, 42 are introduced into the vacuum chamber 1 from the circumferential wall portion of the vacuum chamber 1 in the illustrated example, these gas nozzles 31, 32, 41, 42 may be introduced from a ring-shaped protrusion portion 5 (described later). In this case, an L-shaped conduit may be provided in order to be open on the outer circumferential surface of the protrusion portion 5 and on the outer upper surface of the ceiling plate 11. With such an L-shaped conduit, the gas nozzle 31 (32, 41, 42) can be connected to one opening of the L-shaped conduit inside the vacuum chamber 1 and the gas inlet port 31a (32a, 41a, 42a) can be connected to the other opening of the L-shaped conduit outside the vacuum chamber 1.

Although not shown, the reaction gas nozzle 31 is connected to a gas supplying source of bis (tertiary-butylamino) silane (BTBAS), which is a first source gas, and the reaction gas nozzle 32 is connected to a gas supplying source of O₃ (ozone) gas, which is a second source gas.

The reaction gas nozzles 31, 32 have plural ejection holes 33 to eject the corresponding source gases downward. The plural ejection holes 33 are arranged in longitudinal directions of the reaction gas nozzles 31, 32 at predetermined intervals. The ejection holes 33 have an inner diameter of about 0.5 mm, and are arranged at intervals of about 10 mm in this embodiment. The reaction gas nozzles 31, 32 are a first reaction gas supplying portion and a second reaction gas supplying portion, respectively, in this embodiment. In addition, an area below the reaction gas nozzle 31 is a first process area P1 in which the BTBAS gas is adsorbed on the wafer W, and an area below the reaction gas nozzle 32 is a second process area P2 in which the O₃ gas is adsorbed on the wafer W.

On the other hand, the separation gas nozzles 41, 42 are connected to gas supplying sources of N₂ (nitrogen) gas (not shown). The separation gas nozzles 41, 42 have plural ejection holes 40 to eject the separation gases downward from the plural ejection holes 40. The plural ejection holes 40 are arranged at predetermined intervals in longitudinal directions of the separation gas nozzles 41, 42. The ejection holes 40 have an inner diameter of about 0.5 mm, and are arranged at intervals of about 10 mm in this embodiment.

The separation gas nozzles 41, 42 are provided in separation areas D that are configured to separate the first process area P1 and the second process area P2. In each of the separation areas D, there is provided a convex portion 4 on the ceiling plate 11, as shown in FIGS. 8 through 10. The convex portion 4 has a top view shape of a sector whose apex lies at the center of the vacuum chamber 1 and whose arced periphery lies near and along the inner circumferential wall of the chamber body 12. In addition, the convex portion 4 has a groove portion 43 that extends in the radial direction as if the groove portion 43 has substantially bisected the convex portion 4. The separation gas nozzle 41 (42) is housed in the groove portion 43. A circumferential distance between the center axis of the separation gas nozzle 41 (42) and one side of the sector-shaped convex portion 4 is substantially equal to the other circumferential distance between the center axis of the separation gas nozzle 41 (42) and the other side of the sector-shaped convex portion 4. Incidentally, while the groove portion 43 is formed in order to bisect the convex portion 4 in this embodiment, the groove portion 42 is formed so that an upstream side of the convex portion 4 relative to the rotation direction of the susceptor 2 is wider, in other embodiments.

With the above configuration, there are flat low ceiling surfaces 44 (first ceiling surfaces) on both sides of the separation gas nozzle 41 (42), and high ceiling surfaces 45 (second ceiling surfaces) outside of the corresponding low ceiling surfaces 44, as shown in a subsection (a) of FIG. 10. The convex portion 4 (ceiling surface 44) provides a separation space, which is a thin space, between the convex portion 4 and the susceptor 2 in order to impede the first and the second reaction gases from entering the thin space and from being intermixed.

Referring to a subsection (b) of FIG. 10, the O₃ gas is impeded from entering the space between the convex portion 4 and the susceptor 2, the O₃ gas flowing toward the convex portion 4 from the reaction gas nozzle 32 along the rotation direction of the susceptor 2, and the BTBAS gas is impeded from entering the space between the convex portion 4 and the susceptor 2, the BTBAS gas flowing toward the convex portion 4 from the reaction gas nozzle 31 along the counter-rotation direction of the susceptor 2. “The gases being impeded from entering” means that the N₂ gas as the separation gas ejected from the separation gas nozzle 41 spreads between the first ceiling surfaces 44 and the upper surface of the susceptor 2 and flows out to a space below the second ceiling surfaces 45, which are adjacent to the corresponding first ceiling surfaces 44 in the illustrated example, so that the reaction gases cannot enter the separation space from the space below the second ceiling surfaces 45. “The reaction gases cannot enter the separation space” means not only that the reaction gases are completely prevented from entering the separation space, but that the gases cannot proceed farther toward the separation gas nozzle 41 and thus be intermixed with each other even when a fraction of the reaction gases enter the separation space. Namely, as long as such effect is demonstrated, the separation area D is to separate the first process area P1 and the second process area P2. Incidentally, the BTBAS gas or the O₃ gas adsorbed on the wafer W can pass through below the convex portion 4. Therefore, the reaction gases in “the gases being impeded from entering” mean the reaction gases in a gaseous phase.

Referring to FIGS. 7 through 9, a ring-shaped protrusion portion 5 is provided on a lower surface of the ceiling plate 11 so that the inner circumference of the protrusion portion 5 faces the outer circumference of the core portion 21. The protrusion portion 5 opposes the susceptor 2 at an outer area of the core portion 21. In addition, a lower surface of the protrusion portion 5 and a lower surface of the convex portion 4 form one plane surface. In other words, a height of the lower surface of the protrusion portion 5 from the susceptor 2 is the same as a height of the lower surface of the convex portion 4, which will be referred to as a height h below. Incidentally, the convex portion 4 is formed not integrally with but separately from the protrusion portion 5 in other embodiments. FIGS. 8 and 9 show the inner configuration of the vacuum chamber 1 whose top plate 11 is removed while the convex portions 4 remain inside the vacuum chamber 1.

The separation area D is configured by forming the groove portion 43 in a sector-shaped plate to be the convex portion 4, and locating the separation gas nozzle 41 (42) in the groove portion 43 in this embodiment. However, two sector-shaped plates may be attached on the lower surface of the ceiling plate 11 with screws so that the two sector-shaped plates are located one on each side of the separation gas nozzle 41 (32).

In this embodiment, when the wafer W having a diameter of about 300 mm is supposed to be processed in the vacuum chamber 1, the convex portion 4 has a circumferential length of, for example, about 146 mm along an inner arc (FIG. 9) that is at a distance 140 mm from the rotation center of the susceptor 2, and a circumferential length of, for example, about 502 mm along an outer arc lo (FIG. 9) corresponding to the outermost portion of the substrate receiving portions 24 of the susceptor 2. In addition, a circumferential length from one side wall of the convex portion 4 through the nearest side wall of the groove portion 43 along the outer arc lo is about 246 mm.

In addition, the height h (the subsection (a) of FIG. 4) of the lower surface of the convex portion 4, or the ceiling surface 44, measured from the upper surface of the susceptor 2 (or the wafer W) is, for example, about 0.5 mm through about 10 mm, and preferably about 4 mm. In this case, the rotational speed of the susceptor 2 is, for example, 1 through 500 revolutions per minute (rpm). In order to ascertain the separation function performed by the separation area D, the size of the convex portion 4 and the height h of the ceiling surface 44 from the susceptor 2 may be determined depending on the pressure in the vacuum chamber 1 and the rotational speed of the susceptor 2 through experimentation. Incidentally, the separation gas is N₂ in this embodiment but may be an inert gas such as He and Ar, or H₂ in other embodiments, as long as the separation gas does not affect the deposition of a silicon oxide film.

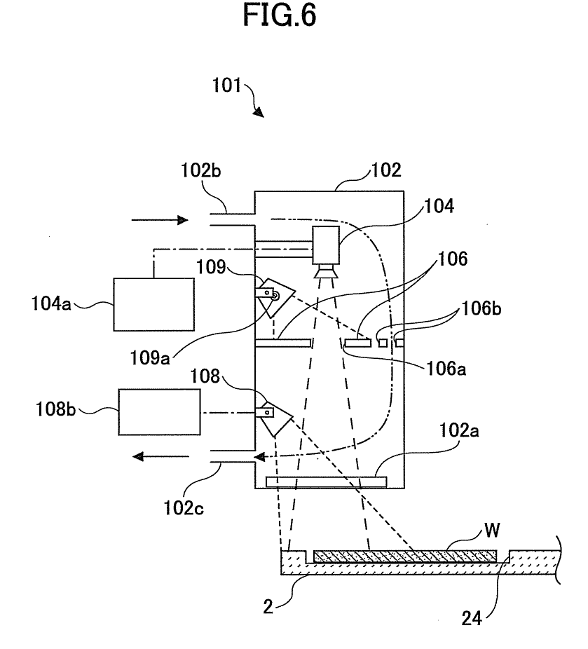

FIG. 6 shows a half portion of a cross-sectional view of the vacuum chamber 1, taken along an A-A line in FIG. 3, where the convex portion 4 is shown along with the protrusion portion 5 formed integrally with the convex portion 4. Referring to FIG. 6, the convex portion 4 has a bent portion 46 that bends in an L-shape at the outer circumferential edge of the convex portion 4. Although there are slight gaps between the bent portion 46 and the susceptor 2 and between the bent portion 46 and the chamber body 12 because the convex portion 4 is attached on the lower surface of the ceiling portion 11 and removed from the chamber body 12 along with the ceiling portion 11, the bent portion 46 substantially fills out a space between the susceptor 2 and the chamber body 12, thereby preventing the first reaction gas (BTBAS) ejected from the first reaction gas nozzle 31 and the second reaction gas (ozone) ejected from the second reaction gas nozzle 32 from being intermixed through the space between the susceptor 2 and the chamber body 12. The gaps between the bent portion 46 and the susceptor 2 and between the bent portion 46 and the chamber body 12 may be the same as the height h of the ceiling surface 44 from the susceptor 2. In the illustrated example, a side wall facing the outer circumferential surface of the susceptor 2 serves as an inner circumferential wall of the separation area D.

Now, referring again to FIG. 7, which is a cross-sectional view taken along a B-B line in FIG. 9, the chamber body 12 has an indented portion at the inner circumferential portion opposed to the outer circumferential surface of the susceptor 2. The indented portion is referred to as an evacuation area 6 hereinafter. Below the evacuation area 6, there is an evacuation port 61 (see FIG. 9 for another evacuation port 62) which is connected to a vacuum pump 64 via an evacuation pipe 63, which can also be used for the evacuation port 62. In addition, the evacuation pipe 63 is provided with a pressure controller 65. Plural pressure controllers 65 may be provided to the corresponding evacuation ports 61, 62.

Referring again to FIG. 9, the evacuation port 61 is located between the first reaction gas nozzle 31 and the convex portion 4 that is located downstream relative to the clockwise rotation direction of the susceptor 2 in relation to the first reaction gas nozzle 31, when viewed from above. With this configuration, the evacuation port 61 can substantially exclusively evacuate the BTBAS gas ejected from the reaction gas nozzle 31. On the other hand, the evacuation port 62 is located between the second reaction gas nozzle 32 and the convex portion 4 that is located downstream relative to the clockwise rotation direction of the susceptor 2 in relation to the second reaction gas nozzle 32, when viewed from above. With this configuration, the evacuation port 62 can substantially exclusively evacuate the O₃ gas ejected from the reaction gas nozzle 32. Therefore, the evacuation ports 61, 62 so configured may assist the separation areas D to prevent the BTBAS gas and the O₃ gas from being intermixed.

Although the two evacuation ports 61, 62 are made in the chamber body 12 in this embodiment, three evacuation ports may be provided in other embodiments. For example, an additional evacuation port may be made in an area between the second reaction gas nozzle 32 and the separation area D located upstream relative to the clockwise rotation of the susceptor 2 in relation to the second reaction gas nozzle 32. In addition, another additional evacuation port may be made at a predetermined position in the chamber body 12. While the evacuation ports 61, 62 are located below the susceptor 2 to evacuate the vacuum chamber 1 through an area between the inner circumferential wall of the chamber body 12 and the outer circumferential surface of the susceptor 2 in the illustrated example, the evacuation ports may be located in the side wall of the chamber body 12. In addition, when the evacuation ports 61, 62 are provided in the side wall of the chamber body 12, the evacuation ports 61, 62 may be located higher than the susceptor 2. In this case, the gases flow along the upper surface of the susceptor 2 into the evacuation ports 61, 62 located higher than the susceptor 2. Therefore, it is advantageous in that particles in the vacuum chamber 1 are not blown upward by the gases, compared to when the evacuation ports are provided, for example, in the ceiling plate 11.

As shown in FIGS. 7, 11, and 12, a ring-shaped heater unit 7 as a heating portion is provided in a space between the bottom portion 14 of the chamber body 12 and the susceptor 2, so that the wafers W placed on the susceptor 2 are heated through the susceptor 2 at a temperature determined by a process recipe. In addition, a cover member 71 is provided beneath the susceptor 2 and near the outer circumference of the susceptor 2 in order to surround the heater unit 7, so that the space where the heater unit 7 is located is partitioned from the outside area of the cover member 71. The cover member 71 has a flange portion 71a at the top. The flange portion 71a is arranged so that a slight gap is maintained between the lower surface of the susceptor 2 and the flange portion in order to prevent gas from flowing inside the cover member 71.

Referring back to FIG. 7, the bottom portion 14 of the chamber body 12 has a raised portion in an inside area of the ring-shaped heater unit 7. The upper surface of the raised portion comes close to the back surface of the susceptor 2 and the core portion 21, leaving slight gaps between the raised portion and the susceptor 2 and between the raised portion and the core portion 21. In addition, the bottom portion 14 has a center hole through which the rotational shaft 22 passes. The inner diameter of the center hole is slightly larger than the diameter of the rotational shaft 22, leaving a gap for gaseous communication with the case body 20 through the flanged pipe portion 20a. A purge gas supplying pipe 72 is connected to an upper portion of the flanged pipe portion 20a. In addition, plural purge gas supplying pipes 73 are connected at predetermined angular intervals to areas below the heater unit 7 in order to purge the space where the heater unit 7 is housed.

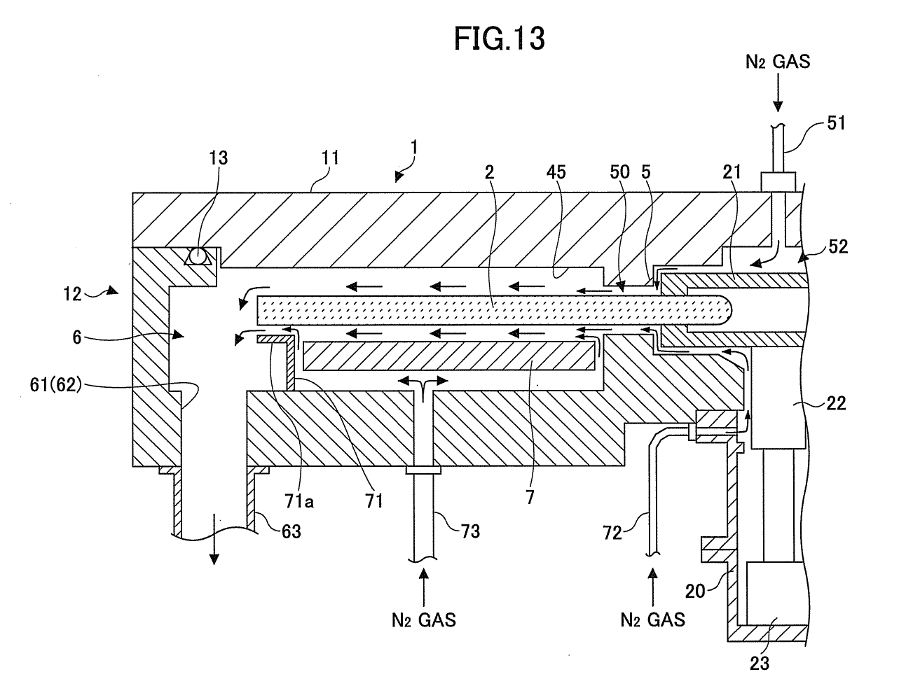

With these configurations, N₂ purge gas may flow from the purge gas supplying pipe 72 to the heater unit space through the gap between the rotational shaft 22 and the center hole of the bottom portion 14, the gap between the core portion 21 and the raised portion of the bottom portion 14, and the gap between the raised portion of the bottom portion 14 and the lower surface of the susceptor 2. In addition, N₂ purge gas may flow from the purge gas supplying pipes 73 to the space below the heater unit 7. Then, these N₂ purge gases flow into the evacuation port 61 through the gap between the flange portion 71a of the cover member 71 and the lower surface of the susceptor 2. These flows of the N₂ purge gases are schematically illustrated by arrows in FIG. 13. These N₂ purge gases serve as separation gases that prevent the first (second) reaction gas from flowing around the space below the susceptor 2 to be intermixed with the second (first) reaction gas.

Referring to FIG. 13, a separation gas supplying pipe 51 is connected to the top center portion of the ceiling plate 11 of the vacuum chamber 1, so that N₂ gas is supplied as a separation gas to a space 52 between the ceiling plate 11 and the core portion 21. The separation gas supplied to the space 52 flows through the thin gap 50 between the protrusion portion 5 and the susceptor 2 and then along the upper surface of the susceptor 2, and reaches the evacuation area 6. Because the space 52 and the gap 50 are filled with the N₂ gas, the reaction gases (BTBAS, O₃) cannot be intermixed through the center portion of the susceptor 2. In other words, the film deposition apparatus according to this embodiment is provided with a center area C that is defined by the center portion of the susceptor 2 and the vacuum chamber 1 in order to isolate the first process area P1 and the second process area P2 and is configured to have an ejection opening that ejects the separation gas toward the upper surface of the susceptor 2. The ejection opening corresponds to the gap 50 between the protrusion portion 5 and the susceptor 2, in the illustrated example.

In addition, the film deposition apparatus 200 according to this embodiment is provided with a control portion 100 that controls total operations of the deposition apparatus 300. The control portion 100 includes a process controller 100a formed of, for example, a computer, a user interface portion 100b, and a memory device 100c. The user interface portion 100b has a display that shows operations of the film deposition apparatus, and a key board or a touch panel (not shown) that allows an operator of the film deposition apparatus 200 to select process programs and an administrator of the film deposition apparatus to change parameters in the process programs.

The memory device 100c stores a control program and a process program that cause the controlling portion 100 to carry out various operations of the deposition apparatus, and various parameters in the process programs. These programs have groups of steps for carrying out the operations described later, for example. These programs are installed into and run by the process controller 100a by instructions from the user interface portion 100b. In addition, the programs are stored in a computer readable storage medium 100d and installed into the memory device 100c from the storage medium 100d through an input/output (I/O) device (not shown) corresponding to the computer readable storage medium 100d. The computer readable storage medium 100d may be a hard disk, a compact disc, a magneto optical disk, a memory card, a floppy disk, or the like. Moreover, the programs may be downloaded to the memory device 100c through a communications network.

The controlling portion 100 of the film deposition apparatus 200 sends/receives a signal to/from the control portion 104a of the substrate position detection apparatus 101. For example, when the controlling portion 100 of the film deposition apparatus 200 receives a signal for inquiring about wafers W with respect to which the position detection is not carried out from the control portion 104a, the controlling portion 100 sends a signal indicating presence/absence of the remaining wafers W to the control portion 104a. In addition, when the controlling portion 100 receives a signal indicating that the wafer W is not positioned in a predetermined position from the control portion 104a, the controlling portion 100 of the film deposition apparatus 200 suspends the film deposition apparatus 200 and brings it into an idle state. Moreover, the controlling portion 100 of the film deposition apparatus 200 may read in a program for causing the substrate position detection apparatus 101 to carry out the substrate position detection method from a predetermined computer readable storage medium through a predetermined input/output device (not shown), and cause the substrate position detection apparatus 101 to carry out the method through the control portion 104a of the substrate position detection apparatus 101 in accordance with the program. Furthermore, the controlling portion 100 of the film deposition apparatus 200 may read in such a program from the predetermined computer readable storage medium through the predetermined input/output device, and forward the program to the control portion 104a of the substrate position detection apparatus 101. In this case, the control portion 104a of the substrate position detection apparatus 101 controls various components and parts of the substrate position detection apparatus 101 to carry out the substrate position detection method.

Next, operations of the film deposition apparatus, or a film deposition method using the film deposition apparatus 200 according to this embodiment of the present invention are described. First, the susceptor 2 is rotated so that the substrate receiving portion 24 is in alignment with the transfer opening 15, and the gate valve (not shown) is opened. Second, the wafer W is brought into the vacuum chamber 1 through the transfer opening 15 by the transfer arm 10. The wafer W is received by the lift pins 16 and lowered to the substrate receiving portion 24 by the lift pins 16 driven by the elevation mechanism (not shown) after the transfer arm 10 is pulled away from the vacuum chamber 1. In such a manner, the wafer W is placed in the substrate receiving portion 24.

Next, the susceptor 2 is rotated by about 72°, and thus the wafer W placed in the substrate receiving portion 24 is positioned below the substrate position detection apparatus 101. Then, the substrate position detection method is carried out with respect to the wafer W. Meanwhile, the next wafer W is placed in the adjacent substrate receiving portion 24 in alignment with the transfer opening 15 by the operations of the transfer arm 10 and the lift pins 16. After the series of operations above is repeated five times and thus five wafers W are loaded on the susceptor 2, or after the wafer W, which has once been determined not to be in a predetermined position, if any, is appropriately manually placed, the vacuum pump 64 (FIG. 7) is activated in order to maintain the vacuum chamber 1 at a predetermined reduced pressure. The susceptor 2 starts rotating clockwise when seen from above. The susceptor 2 is heated to a predetermined temperature (e.g., 300° C.) in advance by the heater unit 7, which in turn heats the wafers W on the susceptor 2. After the wafers W are heated and maintained at the predetermined temperature, which may be confirmed by a temperature sensor (not shown), the first reaction gas (BTBAS) is supplied to the first process area P1 through the first reaction gas nozzle 31, and the second reaction gas (O₃) is supplied to the second process area P2 through the second reaction gas nozzle 32. In addition, the separation gases (N₂) are supplied to the separation areas D through the separation nozzles 41, 42.

When the wafer W passes through the first process area P1 below the first reaction gas nozzle 31, BTBAS molecules are adsorbed on the surface of the wafer W, and when the wafer W passes through the second process area P2 below the second reaction gas nozzle 32, O₃ molecules are adsorbed on the surface of the wafer W, so that the BTBAS molecules are oxidized by the O₃ molecules. Therefore, when the wafer W passes through both areas P1, P2 with one rotation of the susceptor 2, one molecular layer of silicon dioxide is formed on the surface of the wafer W. Then, the wafer W alternately passes through areas P1, P2 plural times, and a silicon dioxide layer having a predetermined thickness is formed on the surfaces of the wafers W. After the silicon dioxide film having the predetermined thickness is deposited, the supply of the BTBAS gas and the supply of the O₃ gas are stopped, and the rotation of the susceptor 2 is stopped.

In addition, during the deposition process above, the N₂ gas as the separation gas is supplied from the separation gas supplying pipe 51, and is ejected toward the upper surface of the susceptor 2 from the center area C, that is, the gap 50 between the protrusion portion 5 and the susceptor 2. In this embodiment, a space below the second ceiling surface 45, where the reaction gas nozzle 31 (32) is arranged, has a lower pressure than the center area C and the thin space between the first ceiling surface 44 and susceptor 2. This is because the evacuation area 6 is provided adjacent to the space below the ceiling surface 45 (see FIGS. 1 and 3) and the space is directly evacuated through the evacuation area 6. Additionally, it is partly because the thin space is provided so that the height h can maintain the pressure difference between the thin space and the place where the reaction gas nozzle 31 (32) or the first (the second) process area P1 (P2) is located.

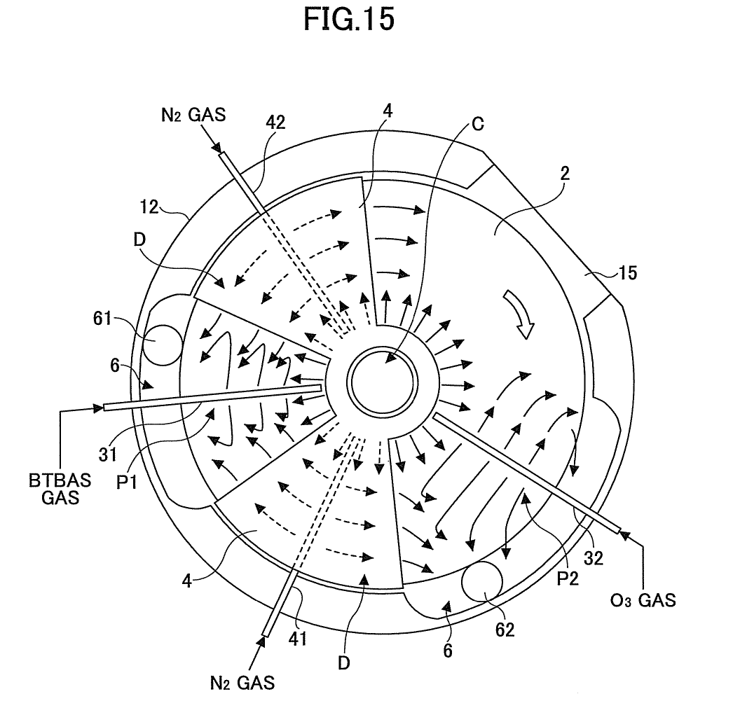

Next, the flow patterns of the gases supplied into the vacuum chamber 1 from the gas nozzles 31, 32, 41, 42 are described in reference to FIG. 15, which schematically shows the flow patterns. As shown, part of the O₃ gas ejected from the second reaction gas nozzle 32 hits and flows along the upper surface of the susceptor 2 (and the surface of the wafer W) in a direction opposite to the rotation direction of the susceptor 2. Then, the O₃ gas is pushed back by the N₂ gas flowing along the rotation direction, and changes the flow direction toward the edge of the susceptor 2 and the inner circumferential wall of the chamber body 12. Finally, this part of the O₃ gas flows into the evacuation area 6 and is evacuated from the vacuum chamber 1 through the evacuation port 62.

Another part of the O₃ gas ejected from the second reaction gas nozzle 32 hits and flows along the upper surface of the susceptor 2 (and the surface of the wafers W) in the same direction as the rotation direction of the susceptor 2. This part of the O₃ gas mainly flows toward the evacuation area 6 due to the N₂ gas flowing from the center portion C and suction force through the evacuation port 62. On the other hand, a small portion of this part of the O₃ gas flows toward the separation area D located downstream of the rotation direction of the susceptor 2 in relation to the second reaction gas nozzle 32 and may enter the gap between the ceiling surface 44 and the susceptor 2. However, because the height h of the gap is designed so that the O₃ gas is impeded from flowing into the gap at film deposition conditions intended, the small portion of the O₃ gas cannot flow into the gap. Even when a small fraction of the O₃ gas flows into the gap, the fraction of the O₃ gas cannot flow farther into the separation area D, because the fraction of the O₃ gas can be pushed backward by the N₂ gas ejected from the separation gas nozzle 41. Therefore, substantially all the part of the O₃ gas flowing along the upper surface of the susceptor 2 in the rotation direction flows into the evacuation area 6 and is evacuated by the evacuation port 62, as shown in FIG. 15.

Similarly, part of the BTBAS gas ejected from the first reaction gas nozzle 31 to flow along the upper surface of the susceptor 2 in a direction opposite to the rotation direction of the susceptor 2 is prevented from flowing into the gap between the susceptor 2 and the ceiling surface 44 of the convex portion 4 located upstream relative to the rotation direction of the susceptor 2 in relation to the first reaction gas nozzle 31. Even if only a fraction of the BTBAS gas flows into the gap, this BTBAS gas is pushed backward by the N₂ gas ejected from the separation gas nozzle 41 in the separation area D. The BTBAS gas pushed backward flows toward the outer circumferential edge of the susceptor 2 and the inner circumferential wall of the chamber body 12, along with the N₂ gases from the separation gas nozzle 41 and the center portion C, and then is evacuated by the evacuation port 61 through the evacuation area 6.

Another part of the BTBAS gas ejected from the first reaction gas nozzle 31 to flow along the upper surface of the susceptor 2 (and the surface of the wafers W) in the same direction as the rotation direction of the susceptor 2 cannot flow into the gap between the susceptor 2 and the ceiling surface 44 of the convex portion 4 located downstream relative to the rotation direction of the susceptor 2 in relation to the first reaction gas supplying nozzle 31. Even if a fraction of this part of the BTBAS gas flows into the gap, this BTBAS gas is pushed backward by the N₂ gases ejected from the center portion C and the separation gas nozzle 42 in the separation area D. The BTBAS gas pushed backward flows toward the evacuation area 6, along with the N₂ gases from the separation gas nozzle 41 and the center portion C, and then is evacuated by the evacuation port 61.

As stated above, the separation areas D may prevent the BTBAS gas and the O₃ gas from flowing thereinto, or may greatly reduce the amount of the BTBAS gas and the O₃ gas flowing thereinto, or may push the BTBAS gas and the O₃ gas backward. The BTBAS molecules and the O₃ molecules adsorbed on the wafer W are allowed to go through the separation area D, contributing to the film deposition.

Additionally, the BTBAS gas in the first process area P1 (the O₃ gas in the second process area 22) is prevented from flowing into the center area C, because the separation gas is ejected toward the outer circumferential edge of the susceptor 2 from the center area C, as shown in FIGS. 13 and 15. Even if a fraction of the BTBAS gas in the first process area P1 (the O₃ gas in the second process area P2) flows into the center area C, the BTBAS gas (the O₃ gas) is pushed backward, so that the BTBAS gas in the first process area 21 (the O₃ gas in the second process area P2) is prevented from flowing into the second process area P2 (the first process area P1) through the center area C.

Moreover, the BTBAS gas in the first process area P1 (the O₃ gas in the second process area P2) is prevented from flowing into the second process area 22 (the first process area P1) through the space between the susceptor 2 and the inner circumferential wall of the chamber body 12. This is because the bent portion 46 is formed downward from the convex portion 4 so that the gaps between the bent portion 46 and the susceptor 2 and between the bent portion 46 and the inner circumferential wall of the chamber body 12 are as small as the height h of the ceiling surface 44 of the convex portion 4, the height h being measured from the susceptor 2, thereby substantially avoiding pressure communication between the two process areas, as stated above. Therefore, the BTBAS gas is evacuated from the evacuation port 61, and the O₃ gas is evacuated from the evacuation port 62, and thus the two reaction gases are not intermixed. In addition, the space below the susceptor 2 is purged by the N₂ gas supplied from the purge gas supplying pipes 72, 73. Therefore, the BTBAS gas cannot flow through below the susceptor 2 into the second process area P2.

An example of process parameters preferable in the film deposition apparatus according to this embodiment is listed below.

rotational speed of the susceptor 2: 1-500 rpm (in the case of the wafer W having a diameter of 300 mm)

pressure in the vacuum chamber 1: 1067 Pa (8 Torr)

wafer temperature: 350° C.

flow rate of BTBAS gas: 100 sccm

flow rate of O₃ gas: 10000 sccm

flow rate of N₂ gas from the separation gas nozzles 41, 42: 20000 sccm

flow rate of N₂ gas from the separation gas supplying pipe 51: 5000 sccm

the number of rotations of the susceptor 2: 600 rotations (depending on the film thickness required)

According to the film deposition apparatus 200 of this embodiment, because the film deposition apparatus 200 has the separation areas D including the low ceiling surface 44 between the first process area P1, to which the BTBAS gas is supplied from the first reaction gas nozzle 31, and the second process area P2, to which the O₃ gas is supplied from the second reaction gas nozzle 32, the BTBAS gas (the O₃ gas) is prevented from flowing into the second process area P2 (the first process area P1) and being intermixed with the O₃ gas (the BTBAS gas). Therefore, MLD (or ALD) mode deposition of silicon dioxide is assuredly performed by rotating the susceptor 2 on which the wafers W are placed in order to allow the wafers W to pass through the first process area P1, the separation area D, the second process area P2, and the separation area D. In addition, the separation areas D further include the separation gas nozzles 41, 42 from which the N₂ gases are ejected in order to further assuredly prevent the BTBAS gas (the O₃ gas) from flowing into the second process area P2 (the first process area P1) and being intermixed with the O₃ gas (the BTBAS gas). Moreover, because the vacuum chamber 1 of the film deposition apparatus according to this embodiment has the center area C having the ejection holes from which the N₂ gas is ejected, the BTBAS gas (the O₃ gas) is prevented from flowing into the second process area P2 (the first process area P1) through the center area C and being intermixed with the O₃ gas (the BTBAS gas). Furthermore, because the BTBAS gas and the O₃ gas are not intermixed, almost no deposits of silicon dioxide are made on the susceptor 2, thereby reducing particle problems.

Incidentally, although the susceptor 2 has the five substrate receiving portions 24 and five wafers W placed in the corresponding substrate receiving portions 24 can be processed in one run in this embodiment, only one wafer W is placed in one of the five substrate receiving portions 24, or the susceptor 2 may have only one substrate receiving portion 24.

In addition, not being limited to MLD of a silicon oxide film, the film deposition apparatus 300 is used to carry out MLD of a silicon nitride film. As a nitriding gas in the case of MLD of silicon nitride, ammonia (NH₃), hydrazine (N₂H₂), and the like are used.

In addition, as a source gas for the silicon oxide or nitride film deposition, dichlorosilane (DOS), hexadichlorosilane (HOD, tris(dimethylamino) silane (3DMAS), tetra ethyl ortho silicate (TEOS), and the like may be used rather than BTBAS.

Moreover, the film deposition apparatus according to an embodiment of the present invention may be used for MLD of an aluminum oxide (Al₂O₃) film using trymethylaluminum (TMA) and O₃ or oxygen plasma, a zirconium oxide (ZrO₂) film using tetrakis(ethylmethylamino) zirconium (TEMAZ) and O₃ or oxygen plasma, a hafnium oxide (HfO₂) film using tetrakis(ethylmethylamino) hafnium (TEMAHf) and O₃ or oxygen plasma, a strontium oxide (SrO) film using bis(tetra methyl heptandionate) strontium (Sr (THD)₂) and O₃ or oxygen plasma, a titanium oxide (TiO) film using (methyl-pentadionate) (bis-tetra-methyl-heptandionate) titanium (Ti (MPD)(THD)) and O₃ or oxygen plasma, and the like, rather than the silicon oxide film and the silicon nitride film.

Because a larger centrifugal force is applied to the gases in the vacuum chamber 1 at a position closer to the outer circumference of the susceptor 2, the BTBAS gas, for example, flows toward the separation area D at a higher speed in the position closer to the outer circumference of the susceptor 2. Therefore, the BTBAS gas is more likely to enter the gap between the ceiling surface 44 and the susceptor 2 in the position closer to the circumference of the susceptor 2. Because of this situation, when the convex portion 4 has a greater width (a longer arc) toward the circumference, the BTBAS gas cannot flow farther into the gap in order to be intermixed with the O₃ gas. In view of this, it is preferable for the convex portion 4 to have a sector-shaped top view, as explained above.

The size of the convex portion 4 (or the ceiling surface 44) is exemplified again below. Referring to subsections (a) and (b) of FIG. 13, the ceiling surface 44 that creates the thin space in both sides of the separation gas nozzle 41 (42) may preferably have a length L ranging from about one-tenth of a diameter of the wafer W through about a diameter of the wafer W, preferably, about one-sixth or more of the diameter of the wafer W along an arc that corresponds to a route through which a wafer center WO passes. Specifically, the length L is preferably about 50 mm or more when the wafer W has a diameter of 300 mm. When the length L is small, the height h of the thin space between the ceiling surface 44 and the susceptor 2 (wafer W) has to be accordingly small in order to effectively prevent the reaction gases from flowing into the thin space. However, when the length L becomes too small and thus the height h has to be extremely small, the susceptor 2 may hit the ceiling surface 44, which may cause wafer breakage and wafer contamination through particle generation. Therefore, measures to damp vibration of the susceptor 2 or measures to stably rotate the susceptor 2 are required in order to avoid the susceptor 2 hitting the ceiling surface 44. On the other hand, when the height h of the thin space is kept relatively greater while the length L is small, a rotational speed of the susceptor 2 has to be lower in order to avoid the reaction gases flowing into the thin gap between the ceiling surface 44 and the susceptor 2, which is rather disadvantageous in terms of production throughput. From these considerations, the length L of the ceiling surface 44 along the arc corresponding to the route of the wafer center WO is preferably about 50 mm or more. However, the size of the convex portion 4 or the ceiling surface 44 is not limited to the above size, but may be adjusted depending on the process parameters and the size of the wafer to be used. In addition, as clearly understood from the above explanation, the height h of the thin space may be adjusted depending on an area of the ceiling surface 44 in addition to the process parameters and the size of the wafer to be used, as long as the thin space has a height that allows the separation gas to flow from the separation area D through the process area P1 (22).

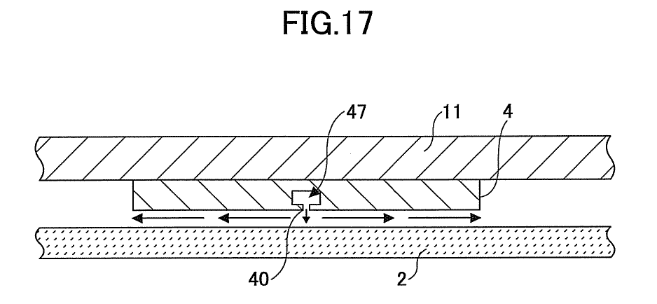

The separation gas nozzle 41 (42) is located in the groove portion 43 formed in the convex portion 4 and the lower ceiling surfaces 44 are located in both sides of the separation gas nozzle 41 (42) in the above embodiment. However, as shown in FIG. 17, a conduit 47 extending along the radial direction of the susceptor 2 may be made inside the convex portion 4, instead of the separation gas nozzle (42), and plural holes 40 may be formed along the longitudinal direction of the conduit 47 so that the separation gas (N₂ gas) may be ejected from the plural holes 40 in other embodiments.

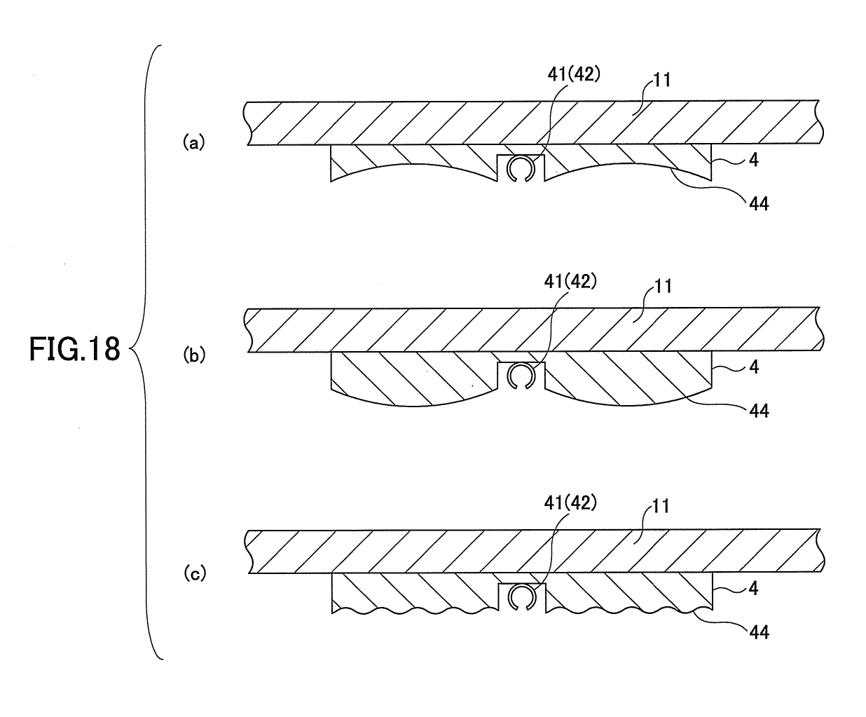

The ceiling surface 44 of the separation area D is not necessarily flat in other embodiments. For example, the ceiling surface 44 may be concavely curved as shown in a subsection (a) of FIG. 18, convexly curved as shown in a subsection (b) of FIG. 18, or corrugated as shown in a subsection (c) of FIG. 18.

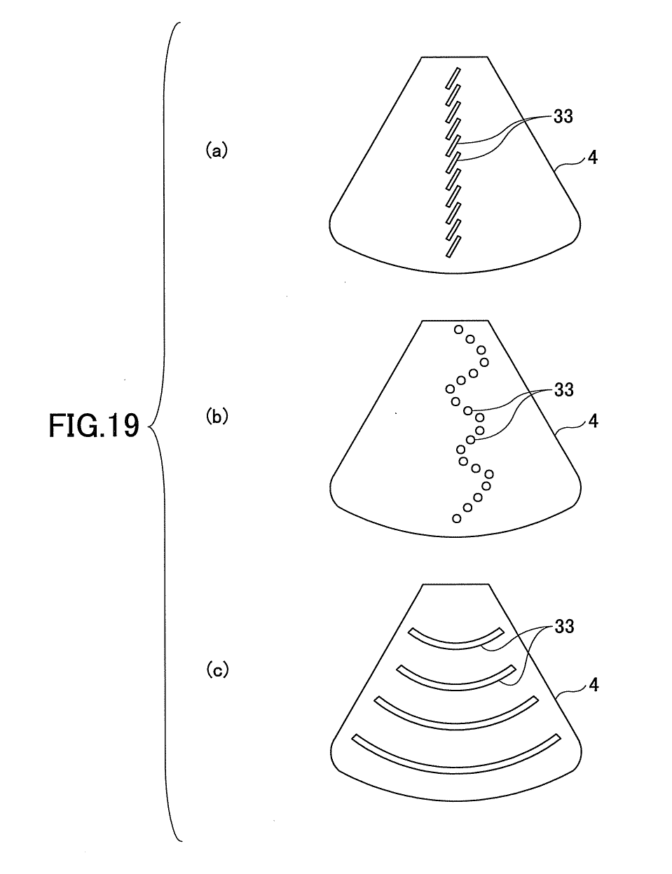

In addition, the convex portion 4 may be hollow and the separation gas may be introduced into the hollow convex portion 4. In this case, the plural gas ejection holes 33 may be arranged as shown in subsections (a) through (c) of FIG. 19.

Referring to the subsection (a) of FIG. 19, each of the plural gas ejection holes 33 has a shape of a slanted slit. These slanted slits (gas ejection holes 33) are arranged to be partially overlapped with an adjacent slit along the radial direction of the susceptor 2. In the subsection (b) of FIG. 19, the plural gas ejection holes 33 are circular. These circular holes (gas ejection holes 33) are arranged along a serpentine line that extends in the radial direction as a whole. In the subsection (c) of FIG. 19, each of the plural gas ejection holes 33 has the shape of an arc-shaped slit. These arc-shaped slits (gas ejection holes 33) are arranged at predetermined intervals in the radial direction.

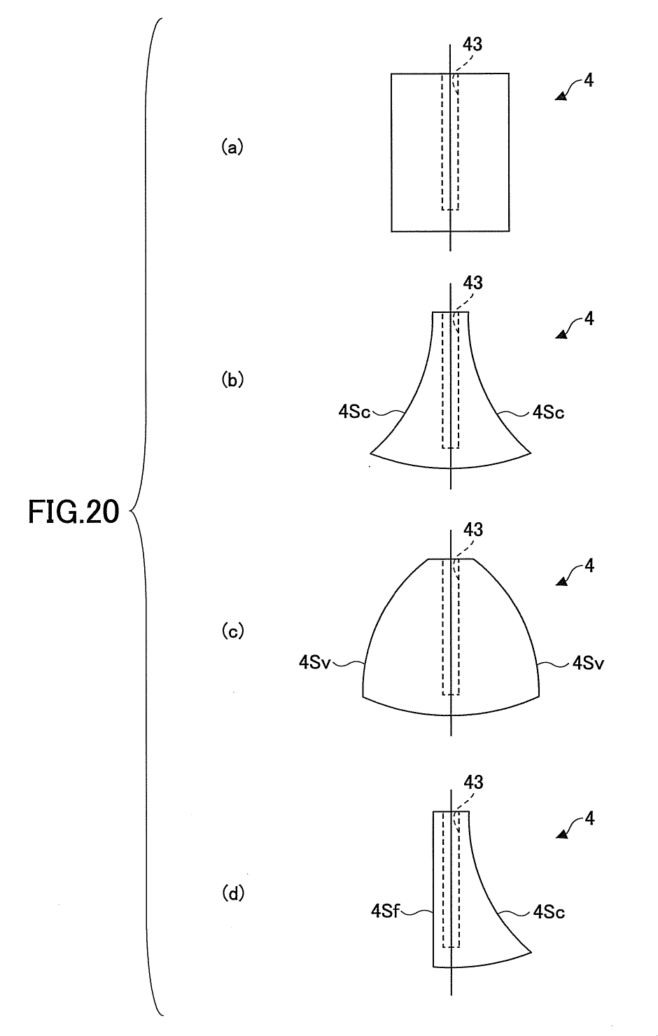

While the convex portion 4 has the sector-shaped top view shape in this embodiment, the convex portion 4 may have a rectangle top view shape as shown in a subsection (a) of FIG. 20, or a square top view shape in other embodiments. Alternatively, the convex portion 4 may be sector-shaped as a whole in the top view and have concavely curved side surfaces 4Sc, as shown in a subsection (b) of FIG. 20. In addition, the convex portion 4 may be sector-shaped as a whole in the top view and have convexly curved side surfaces 4Sv, as shown in a subsection (c) of FIG. 20. Moreover, an upstream portion of the convex portion 4 relative to the rotation direction of the susceptor 2 (FIG. 7) may have a concavely curved side surface 4Sc and a downstream portion of the convex portion 4 relative to the rotation direction of the susceptor 2 (FIG. 7) may have a flat side surface 4Sf, as shown in a subsection (d) of FIG. 20. Incidentally, dotted lines in the subsections (a) through (d) of FIG. 20 represent the groove portions 43. In these cases, the separation gas nozzle 41 (42) (FIG. 8), which is housed in the groove portion 43, extends from the center portion of the vacuum chamber 1, for example, from the protrusion portion 5 (FIG. 7).

The heater unit 7 for heating the wafers W is configured to have a lamp heating element instead of the resistance heating element. In addition, the heater unit 7 may be located above the susceptor 2, or above and below the susceptor 2.

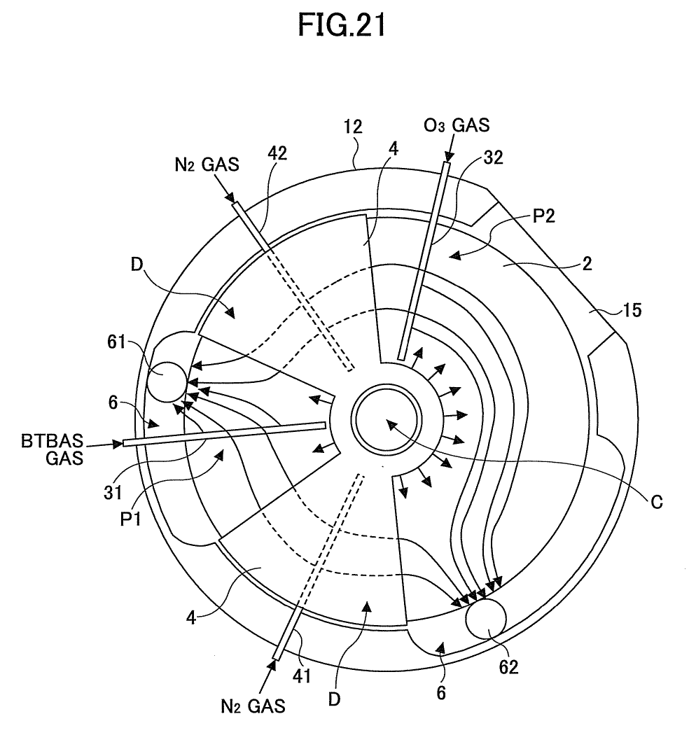

The process areas 91, 92 and the separation area D may be arranged as shown in FIG. 21, in other embodiments. Referring to FIG. 21, the second reaction gas nozzle 32 for supplying the second reaction gas (e.g., O₃ gas) is located upstream in the rotation direction relative to the transfer opening 15, or between the separation gas nozzle 42 and the transfer opening 15. Even in such an arrangement, the gases ejected from the nozzle 31, 32, 41, 42 and the center area C flow generally along arrows shown in FIG. 21, so that the first reaction gas and the second reaction gas cannot be intermixed. Therefore, a proper MLD (or ALD) mode film deposition can be realized by such an arrangement.

In addition, the separation area D may be configured by attaching two sector-shaped plates on the lower surface of the ceiling plate 1 with screws so that the two sector-shaped plates are located one on each side of the separation gas nozzle 41 (42), as stated above. FIG. 19 is a plan view of such a configuration. In this case, the distance between the convex portion 4 and the separation gas nozzle 41 (42), and the size of the convex portion 4 can be determined taking into consideration ejection rates of the separation gas and the reaction gas in order to effectively demonstrate the separation function of the separation area D.

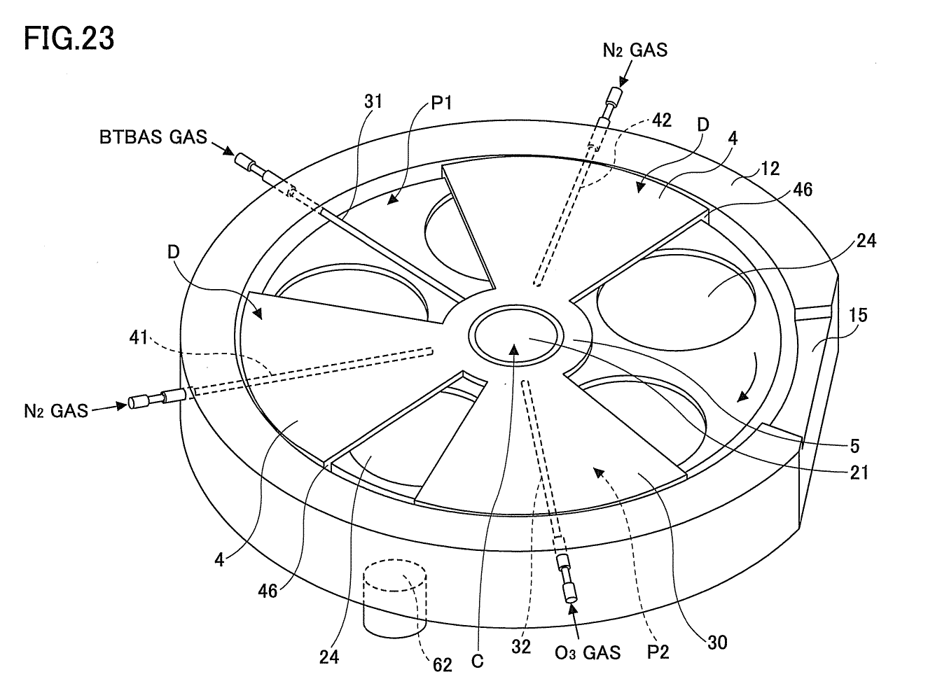

In the above embodiment, the first process area P1 and the second process area 92 correspond to the areas having the ceiling surface 45 higher than the ceiling surface 44 of the separation area D. However, at least one of the first process area P1 and the second process area P2 may have another ceiling surface that opposes the susceptor 2 in both sides of the reaction gas supplying nozzle 31 (32) and is lower than the ceiling surface 45 in order to prevent gas from flowing into a gap between the ceiling surface concerned and the susceptor 2. This ceiling surface, which is lower than the ceiling surface 45, may be as low as the ceiling surface 44 of the separation area D. FIG. 23 shows an example of such a configuration. As shown, a sector-shaped convex portion 30 is located in the second process area P2, where O₃ gas is adsorbed on the wafer W, and the reaction gas nozzle 32 is located in the groove portion (not shown) formed in the convex portion 30. In other words, this second process area P2 shown in FIG. 20 is configured in the same manner as the separation area D, while the gas nozzle is used in order to supply the reaction gas. In addition, the convex portion 30 may be configured as a hollow convex portion, an example of which is illustrated in the subsections (a) through (c) of FIG. 19.

Moreover, the ceiling surface, which is lower than the ceiling surface 45 and as low as the ceiling surface 44 of the separation area D, may be provided for both reaction gas nozzles 31, 32 and extended to reach the ceiling surfaces 44 in other embodiments, as shown in FIG. 21, as long as the low ceiling surfaces 44 are provided on both sides of the reaction gas nozzle 41 (42). In other words, another convex portion 400 may be attached on the lower surface of the ceiling plate 11, instead of the convex portion 4. Referring to FIG. 21, the convex portion 400 has the shape of a substantially circular plate, opposes substantially the entire upper surface of the susceptor 2, has four slots 400a where the corresponding gas nozzles 31, 32, 41, 42 are housed, the slots 400a extending in a radial direction, and leaves a thin space below the convex portion 400 in relation to the susceptor 2. A height of the thin space may be comparable with the height h stated above. When the convex portion 400 is employed, the reaction gas ejected from the reaction gas nozzle 31 (32) spreads to both sides of the reaction gas nozzle 31 (32) below the convex portion 400 (or in the thin space) and the separation gas ejected from the separation gas nozzle 41 (42) diffuses to both sides of the separation gas nozzle 41 (42). The reaction gas and the separation gas flow into each other in the thin space and are evacuated through the evacuation port 61 (62). Even in this case, the reaction gas ejected from the reaction gas nozzle 31 cannot be intermixed with the other reaction gas ejected from the reaction gas nozzle 32, thereby realizing a proper MLD (or ALD) mode film deposition.

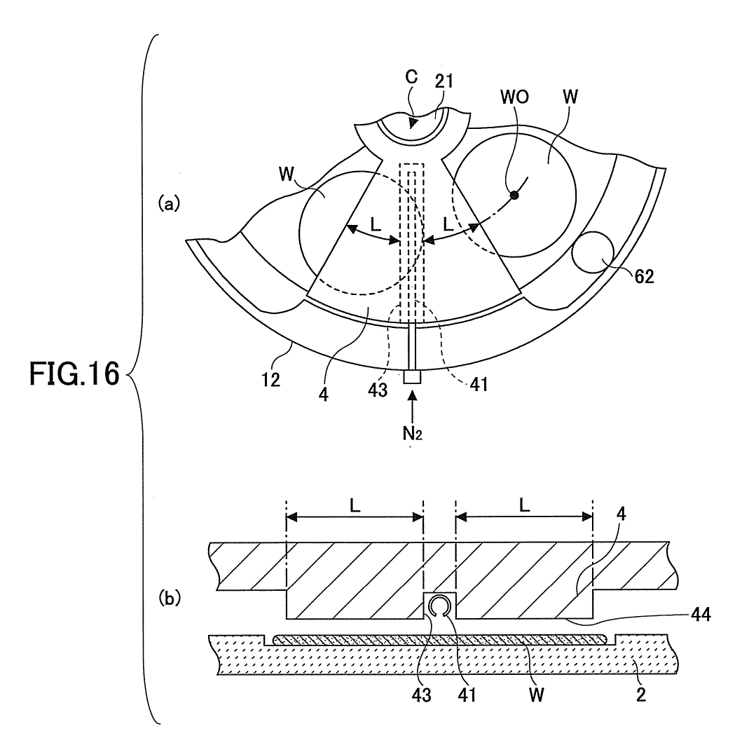

Incidentally, the convex portion 400 may be configured by combining the hollow convex portions 4 shown in any section of FIG. 16 in order to eject the reaction gases and the separation gases from the corresponding ejection holes 33 in the corresponding hollow convex portions 4 without using the gas nozzles 31, 32, 41, 42 and the slits 400a.

In addition, the preferred convex portion 400 is made of, for example, quartz, which allows the substrate position detection apparatus 101 to detect a position of the wafer W through the convex portion 400.

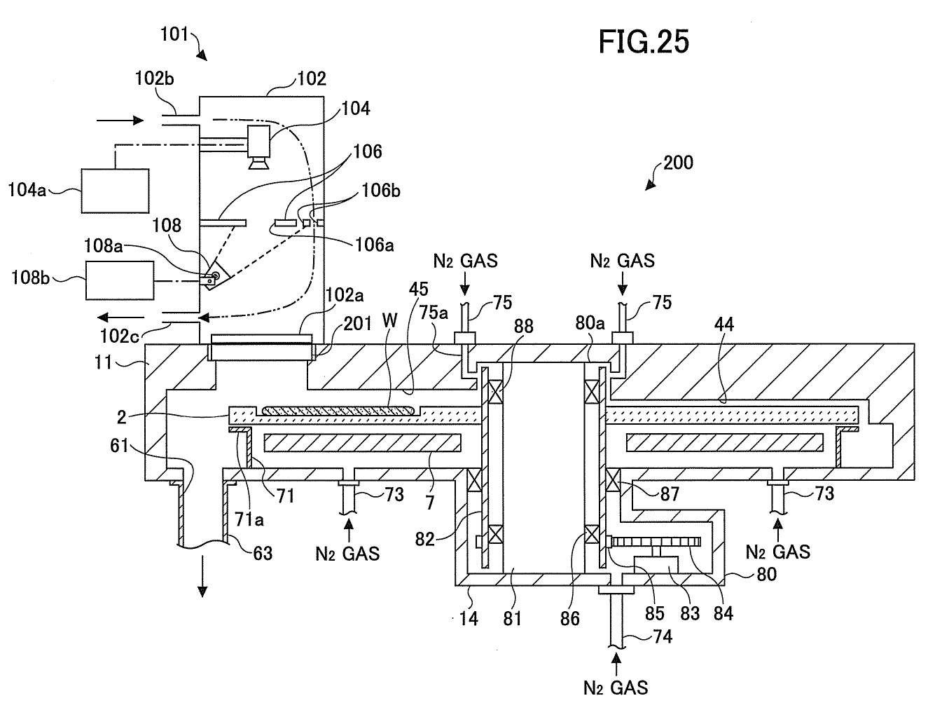

In the above embodiments, the rotational shaft 22 for rotating the susceptor 2 is located in the center portion of the vacuum chamber 1. In addition, the space 52 between the core portion 21 and the ceiling plate 11 is purged with the separation gas in order to prevent the reaction gases from being intermixed through the center portion. However, the vacuum chamber 1 may be configured as shown in FIG. 25 in other embodiments. Referring to FIG. 25, the bottom portion 14 of the chamber body 12 has a center opening to which a housing case 80 is hermetically attached. Additionally, the ceiling plate 11 has a center concave portion 80a. A pillar 81 is placed on the lower surface of the housing case 80, and a top end portion of the pillar 81 reaches a lower surface of the center concave portion 80a. The pillar 81 can prevent the first reaction gas (BTBAS) ejected from the first reaction gas nozzle 31 and the second reaction gas (O₃) ejected from the second reaction gas nozzle 32 from being intermixed through the center portion of the vacuum chamber 1.

In addition, a viewport 201 made of, for example, quartz is hermetically provided in the ceiling plate 11 via a sealing member such as an O ring (not shown). The substrate position detection apparatus 101 is placed on the upper surface of the ceiling plate 11 so that the window 102a of the substrate position detection apparatus 101 faces the viewport 201. The substrate position detection apparatus 101 is configured as explained above, and thus the repetitive explanation is omitted. Use of the substrate position detection apparatus 101 makes it possible to carry out the substrate position detection method to detect a position of the wafer W (FIG. 7) on the susceptor 2 of the film deposition apparatus 200.

In addition, a rotation sleeve 82 is provided so that the rotation sleeve 82 coaxially surrounds the pillar 81. The rotation sleeve 82 is supported by bearings 86, 88 attached on an outer surface of the pillar 81 and a bearing 87 attached on an inner side wall of the housing case 80. Moreover, the rotation sleeve 82 has a gear portion 85 formed or attached on an outer surface of the rotation sleeve 82. Furthermore, an inner circumference of the ring-shaped susceptor 2 is attached on the outer surface of the rotation sleeve 82. A driving portion 83 is housed in the housing case 80 and has a gear 84 attached to a shaft extending from the driving portion 83. The gear 84 is meshed with the gear portion 85. With such a configuration, the rotation sleeve 82 and thus the susceptor 2 are rotated by the driving portion 83.

A purge gas supplying pipe 74 is connected to an opening formed in a bottom of the housing case 80, so that a purge gas is supplied into the housing case 80. With this, an inner space of the housing case 80 may be kept at a higher pressure than an inner space of the chamber 1, in order to prevent the reaction gases from flowing into the housing case 80. Therefore, no film deposition takes place in the housing case 80, thereby reducing maintenance frequency. In addition, purge gas supplying pipes 75 are connected to corresponding conduits 75a that reach from an upper outer surface of the chamber 1 to an inner side wall of the concave portion 80a, so that a purge gas is supplied toward an upper end portion of the rotation sleeve 82. Because of the purge gas, the BTBAS gas and the O₃ gas cannot be mixed through a space between the outer surface of the rotation sleeve 82 and the side wall of the concave portion 80a. Although the two purge gas supplying pipes 75 are illustrated in FIG. 25, the number of the pipes 75 and the corresponding conduits 75a may be determined so that the purge gas from the pipes 75 can assuredly prevent gas mixture of the BTBAS gas and the O₃ gas in and around the space between the outer surface of the rotation sleeve 82 and the side wall of the concave portion 80a.

In the embodiment illustrated in FIG. 25, a space between the side wall of the concave portion 80a and the upper end portion of the rotation sleeve 82 corresponds to the ejection hole for ejecting the separation gas. In addition, the center area located at a center portion of the vacuum chamber 1 is configured with the ejection hole, the rotation sleeve 82, and the pillar 81.

Although the two kinds of reaction gases are used in the film deposition apparatus 300 according to the above embodiment, three or more kinds of reaction gases may be used in other film deposition apparatuses according to other embodiments of the present invention. In this case, a first reaction gas nozzle, a separation gas nozzle, a second reaction gas nozzle, a separation gas nozzle, and a third reaction gas nozzle may be located in this order at predetermined angular intervals, each nozzle extending along the radial direction of the susceptor 2. Additionally, the separation areas D including the corresponding separation gas nozzles are configured the same as explained above.

Because the film deposition apparatus 200 of the embodiments of the present invention is provided with the substrate position detection apparatus 101 according to the embodiment of the present invention, the position of the wafer W can be accurately detected.

The film deposition apparatus 300 according to embodiments of the present invention may be integrated into a wafer process apparatus, an example of which is schematically illustrated in FIG. 25. The wafer process apparatus includes an atmospheric transfer chamber 202 in which a transfer arm 103 is provided, a load lock chamber (preparation chamber) 105 whose atmosphere is changeable between vacuum and atmospheric pressure, a vacuum transfer chamber 206 in which two transfer arms 107a, 107b are provided, and film deposition apparatuses 208, 209 according to embodiments of the present invention. In addition, the wafer process apparatus includes cassette stages (not shown) on which a wafer cassette 101 such as a Front Opening Unified Pod (FOUP) is placed. The wafer cassette 101 is brought onto one of the cassette stages, and connected to a transfer in/out port provided between the cassette stage and the atmospheric transfer chamber 202. Then, a lid of the wafer cassette (FOUP) 101 is opened by an opening/closing mechanism (not shown) and the wafer is taken out from the wafer cassette 101 by the transfer arm 103. Next, the wafer is transferred to the load lock chamber 204 (105). After the load lock chamber 204 (105) is evacuated, the wafer in the load lock chamber 204 (105) is transferred further to one of the film deposition apparatuses 208, 209 through the vacuum transfer chamber 206 by the transfer arm 107a (107b). In the film deposition apparatus 208 (209), a film is deposited on the wafer in such a manner as described above. Because the wafer process apparatus has two film deposition apparatuses 208, 209 that can house five wafers at a time, the MLD (or ALD) mode deposition can be performed at high throughput.

While the present invention has been described with reference to the foregoing embodiments, the present invention is not limited to the disclosed embodiments, but may be modified or altered within the scope of the accompanying claims.

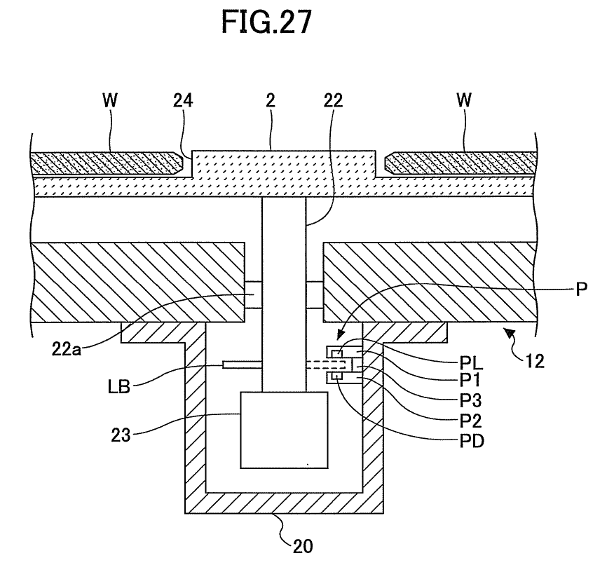

For example, the substrate position detection apparatus and the substrate position detection method using the same may be modified in order to adjust an original position (or beginning position) of the susceptor on which the wafers are placed in various semiconductor device fabrication apparatuses. In the following, original point adjustment is explained with reference to FIGS. 27 through 29.

FIG. 27 is an enlarged schematic view illustrating a susceptor rotation mechanism of the film deposition apparatus 200 shown in FIG. 1 or 7. As shown, the film deposition apparatus 200 provided with the substrate position detection apparatus 101 (FIG. 1) according to the embodiment of the present invention includes the rotational shaft 22 connected to a center portion of the lower surface of the susceptor 2, a driving portion 23 that rotates a susceptor 2 connected to the rotational shaft, thereby rotating the rotational shaft 22, and a case body 20 that hermetically houses the rotational shaft 22 and the driving portion 23. In addition, a sealing member 22a employing, for example, a magnetic fluid is provided between the rotational shaft 22 and the chamber 12, thereby isolating an inside atmosphere of the case body 20 from an inside atmosphere of the chamber 12. A photo sensor P as a stator is attached on an inside wall of the case body 20. The photo sensor P has an upper piece portion P1, a lower piece portion P2, and a middle portion P3 for coupling the upper piece portion P1 and the lower piece portion P2, thereby having substantially a U-shape. A light emitting element PL that emits light downwardly is provided in a lower surface of the upper piece portion P1, and a photo detector PD that detects the light from the light emitting element PL is provided in an upper surface of the lower piece portion P2. On the other hand, a light blocking pin (kicker) LB as a rotating piece is provided on an outer circumferential surface of the rotational shaft 22. A vertical position of the light blocking pin LB is determined so that the light blocking pin LB passes through a space between the upper piece portion 21 and the lower piece portion P1 when rotated by the rotational shaft 22. With this, the light blocking pin LB blocks the light traveling from the light emitting element PL through the photo detector PD when the light blocking pin LB passes through the space between the upper piece portion P1 and the lower piece portion P1. When the light is blocked, an output signal from the photo sensor P is changed, based on which it can be recognized that the light blocking pin LB passes through the space. Therefore, when the attachment position of the light blocking pin LB is associated with a certain position of the susceptor 2, the position of the susceptor 2 can be recognized from the change in the output signal from the photo sensor P. Specifically, the attachment position of the light blocking pin LB (a position along the outer circumferential surface of the rotational shaft 22) is preferably in agreement with the position detection mark 2a of the susceptor 2, for example. With this, when the light blocking pin LB is positioned between the upper piece portion P1 and the lower piece portion P2, the position of the position detection mark 2a of the susceptor 2 can be recognized. In addition, five light blocking pins LB corresponding to the five position detection marks 2a may be attached on the rotational shaft 22.

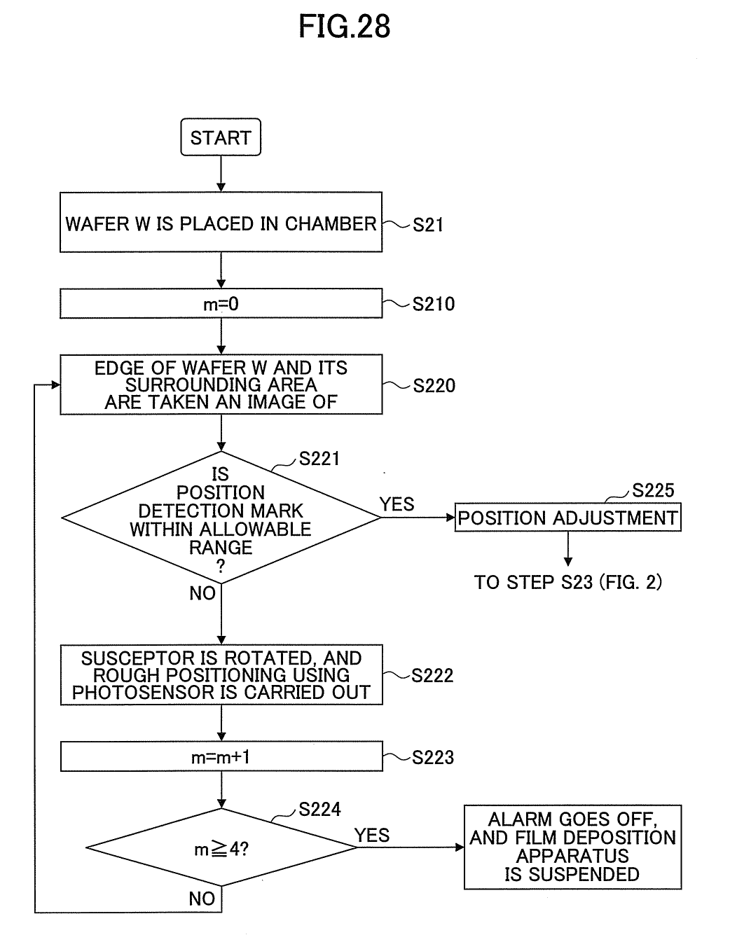

With such a configuration and the substrate position detection apparatus 101 (FIG. 1), the original position of the susceptor 2 can be adjusted, as shown in FIG. 28. First, at Step S21, one wafer W is placed in the substrate receiving portion 24 of the susceptor 2, and at Step 522, a counter m is set as zero. Next, the susceptor 2 is rotated so that an edge area of the wafer W is within the field of view F (FIG. 9) of the substrate position detection apparatus 101. Then, an image of the area including the edge of the wafer W is taken, and the control portion 104a (FIG. 1) determines whether the position detection mark 2a is within a permissible range (Step S221). Specifically, it is determined whether the position detection mark 2a is out of an appropriate position that enables an appropriate estimation of the center position of the susceptor 24 but within a range (the permissible range) from which the position detection mark 2a can be adjusted into the appropriate position. The permissible range may be determined to be, for example, the entire field of view F (excluding the appropriate range), or a certain range having a similarity shape including inside the appropriate range.

When the position detection mark 2a is not within the permissible range (Step S221: NO), the control portion 104a of the substrate position detection apparatus 101 outputs an instruction signal to a control portion of the film deposition apparatus 200, which causes the susceptor 2 to start rotating and then to be stopped so that the position detection mark 2a is within the permissible range of the position detection mark 2a by use of the photo sensor P and the light blocking pin LB (Step S222). Namely, a rough positioning is carried out employing the photo sensor P and the light blocking pin LB. Next, the counter m is incremented by 1 (Step S223); and it is determined whether the counter m is four or more (Step S224). When the counter m is less than 3, the procedure is returned to Step S220 (Step S223: NO).

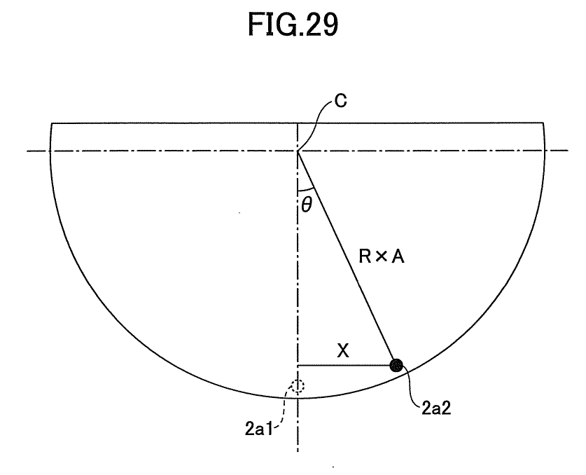

Next, at Step S220, an image of the area including the edge of the wafer W is taken, and then it is determined again whether the position detection mark 2a is within the permissible range (Step S221). When it is determined that the position detection mark 2a is within the permissible range (Step S221: YES), positioning is carried out in order to position the position detection mark 2a in the appropriate position (Step S225). This positioning is carried out, for example, as shown in FIG. 29. FIG. 19 schematically illustrates an image taken by the substrate position detection apparatus 101 at Step S225, where the position detection mark 2a determined to be within the permissible range is indicated by a reference symbol 2a2. In order to move the position detection mark 2a2 into the appropriate position (original point) 2a1, first, the position (for example, coordinate points) of the position detection mark 2a2 within the permissible range is detected. In accordance with the detection result, a line connecting the center C of the susceptor 2 and the appropriate position 2a1 that has been known and a distance X (in a unit of dots) are calculated. When it is assumed that an angle defined by the position detection mark 2a, the center C of the susceptor 2, and the appropriate position 2a1 is θ, the following relationship is obtained.

(R×A)×sin θ=X (6)

where

R is a known distance between the center C of the susceptor 2 and the position detection mark 2a2 (mm), and

A is the number of dots per unit length.

Therefore, the angle θ is obtained by:

θ=arcsin(X/(R×A)). (7)

When the susceptor 2 is rotated by the angle θ obtained above, the position detection mark 2a is positioned to the appropriate position 2a1. For example, when the driving portion 23 is configured to include a pulse motor, and when 90,000 pulses supplied to the pulse motor correspond one rotation of the susceptor 2 in this case, θ×250 pulses are supplied to the pulse motor, thereby bringing the position detection mark 2a2 into the appropriate position gal.

Subsequently, the procedure goes onto Step S23 in the flowchart of FIG. 2, and the position detection is carried out in accordance with the flowchart of FIG. 2.

On the other hand, when the position detection mark 2a is not within the permissible range (Step S221: NO), Steps S222 through 3224 are repeated and the procedure goes back to Step S220. Then, an image of the area including the edge of the wafer W is taken, and it is determined whether the position detection mark 2a is within the permissible range. When the position detection mark 2a is within the permissible range, (Step S221: YES), the above rough positioning is carried out at Step S225. When the position detection mark 2a is not within the permissible range (Step S221: NO), Steps S222 through 5224 are repeated.

When the counter m is determined to be 4, the procedure goes onto Step S27 (Step S224), where an alarm goes off and a signal for requesting suspension of the film deposition apparatus 200 is transmitted from the control portion 104a to the film deposition apparatus 200, and thus the film deposition apparatus 200 is brought to an idle state. Namely, even after the rough positioning employing the photo sensor P and the light blocking pin LB is repeated three times, if the position detection mark 2a is not within the permissible range, the film deposition apparatus 200 is brought into an idle state. In this case, an operator of the film deposition apparatus 200 manually carries out recovery operations.

According to this modification example of the substrate position detection apparatus 101 and the substrate position detection method using the same, a semiconductor device fabrication apparatus, where a substrate position is to be detected, such as the film deposition apparatus 200 is provided with a simple photo sensor P and light blocking pin (kicker) LB, thereby enabling adjustment of an original position of the susceptor on which a substrate is placed. As an alternative method of adjusting the original position, there may be a method where the original position is adjusted in accordance with information about the original position of the susceptor stored in a control portion of the semiconductor device fabrication apparatus or the substrate position detection apparatus. However, an algorithm for position detecting and/or position adjustment may be complicated. On the other hand, only a minor modification of the substrate position detection apparatus 101 and the substrate position detection method using the same enables the original position detection of the susceptor 2.

In addition, while the original position detection of the susceptor 2 can be generally carried out only by the photo sensor P and the light blocking pin LB, because the susceptor 2 of the film deposition apparatus 200 according to the embodiment of the present invention has a diameter for receiving five twelve-inch wafers, detection errors cannot be neglected even if the position adjustment is carried out by employing the photo sensor P attached on the outer circumferential surface of the rotational shaft 22 having a relatively small diameter and the light blocking pin LB corresponding to the photo sensor P. In order to improve detection accuracy in this case, the light blocking pin may be attached on an outer circumferential of the susceptor 2, for example. However, the photo sensor P cannot be provided inside the chamber 12 of the film deposition apparatus 200 so that the light path is blocked by the ling blocking pin LB because the susceptor 2 is heated to a high temperature. According to this modification example of the substrate position detection apparatus 101, the photo sensor P and the light blocking pin LB can be placed in an appropriate atmosphere and accurately detect a position of the susceptor 2.

In addition, the modification example of the substrate position detection method shown in FIG. 28 may be further modified for use in positioning the susceptor 2 so that the substrate receiving portion 24 is aligned with the transfer opening 15 before the wafer W is transferred into the chamber 12 and placed in the substrate receiving portion 24. In other words, Steps S210 through S224 (S27) of the flowchart in FIG. 28 are carried out before Step S21, an image of the edge of the substrate receiving portion 24 of the susceptor 2 at Step S220 and the position detection mark 2a may be taken (no wafer W is placed at this stage).

Incidentally, a mechanical switch may be used in place of the photo sensor 2, so that the mechanical switch is turned on when a predetermined pin attached on the rotational shaft 22 hits the mechanical switch.

In addition, there is another modification example of the substrate position detection apparatus 101 according to an embodiment of the present invention, as explained below. While the light source 108 is placed between the panel 106 and the window 102a in the above embodiments, a light source 109 may be attached above the panel 106 on the inner wall of the chassis 102, and illuminate an upper surface (a surface facing the camera 104) of the panel 106, as shown in FIG. 6. The light source 109 may include a white LED in the same manner as the light source 108. Even in this case, because the panel 106 has light scattering properties, the light illuminating the upper surface of the panel 106 is scattered in various ways when transmitting through the panel 106, which is accompanied with multiple reflection caused between the upper and the lower surfaces of the panel 106, thereby allowing the entire panel 106 to appear uniformly bright. Therefore, the same advantages demonstrated by the substrate position detection apparatus 101 are obtained by the substrate position detection apparatus 101 shown in FIG. 6. Incidentally, the light source 109 may be provided in addition to the light source 108 provided between the panel 106 and the window 102a. In this case, the light source 108 can be used to illuminate the susceptor 2 in order detect the position of the susceptor 2 (explained later).

While the panel 106 is made of an acrylic plate painted with white pigment and has a milky white color in the above embodiments, the panel 106 may be made of various materials, not being limited to acryl, as long as the panel 106 allows the wafer W to appear uniformly bright. For example, the panel 106 may be made of resins containing light scattering particles such as silica particles, silicon particles, and the like, or a resin plate or a glass plate having a roughened surface. In addition, the panel 106 may be once made of a transparent resin or glass plate and then one or both surface(s) may be roughened. In this case, roughening may be carried out by sandblasting, mechanical grinding using a grind stone or the like, or etching. Moreover, the panel 106 may be made of a resin or glass plate having plural micro-array lenses on one or both surface (s). Furthermore, the color of the pigment applied to the panel 106 is not limited to white, but may be various colors, as long as the wafer W can be indirectly illuminated by the panel 106.

In addition, the panel 106 does not necessarily have a shape of a flat plate, but may have a shape of a dome, a cone, a truncated pyramid (inverted or not), or the like, as long as the panel 106 has an opening that allows the camera 104 to take an image of the edge of the wafer W and its surrounding area.

Moreover, there may be provided a light source that illuminates the panel 106 from a side surface (or an edge) of the panel 106. In this case, the panel 106 preferably has a microlens array in one or both surface(s), which allows the panel 106 to appear uniformly bright when illuminated.

Furthermore, a light source may be configured integrally with the panel 106. For example, the panel 106 so configured may be obtained by placing plural white LEDs (LED chips) on a first plate member having the light scattering properties and the opening 106a, connecting wires to each LED (chip) in order to supply electricity, and attaching a second plate member having the opening 106a so that the LEDs (chips) are interposed between the first and the second plate members. Even with this configuration, the first plate member having the light scattering properties can appear uniformly bright when electricity is supplied to each LED (chip). In other words, the first plate member serves as the panel 106 exemplified in the above embodiments. In addition, the second plate member may or may not have the light scattering properties in this modification. Alternatively, the second plate member may have a light reflection surface facing the first plate member.

Additionally, while an image of the edge of the wafer W and its surrounding area are taken by being illuminated from the lower surface of the panel 106 illuminated by the light source 108 at Step S22 of the substrate position detection method, the light source 108 may be swiveled to face toward the wafer W in order to illuminate the edge of the wafer W and its surrounding area when the position detection mark 2a is detected, which makes it possible to accurately detect the position detection mark 2a. Incidentally, when the panel 106 is illuminated from the side surface thereof or the upper surface thereof, or when the light source incorporated panel 106 is used, the edge of the wafer W and its surrounding area is preferably illuminated by the light source 108 (see FIG. 6) provided between the panel 106 and the window 102a at the time of detecting the position detection mark 2a.

While the center position. C of the substrate receiving portion 24 of the susceptor 2 is estimated in accordance with the position detection mark 2a formed in the susceptor 2 in the substrate position detection method according to an embodiment of the present invention, an edge shape of the substrate receiving portion 24 may be used to estimate the center position C of the substrate receiving portion 24. In addition, it may be determined in accordance with a distance between the edge of the wafer W and the edge of the substrate receiving portion 24 whether the wafer W is placed in a predetermined position.

In addition, the substrate receiving portion 24 is not necessarily formed by a circular concave shape, but may be formed by guide members arranged at predetermined angular intervals to contact the edge of the wafer W, thereby positioning the wafer W. For example, the substrate receiving portion 24 may include an electrostatic chuck.

Even in these cases, the center position C of the substrate receiving portion 24, with which the center position WO of the wafer W is to be in agreement, can be estimated by detecting the position detection mark 2a; the center position WO of the wafer W can be estimated by detecting the edge of the wafer W; and it can be determined by comparing the center portions WO, C whether the wafer W is placed in a predetermined position.

While the CCD camera is used as the camera 104 in the above embodiment, a complementary metal oxide semiconductor (CMOS) camera may be used as the camera 104. In addition, the camera 104 may be a video camera.

The light source 108 may include a halogen lamp or a xenon lamp rather than the white LED 108a. A color of the light from the light source 108 is not limited to white, as long as the light includes spectrum to which the camera 104 is sensitive. In this case, a relatively high brightness of color such as yellow, orange, or green is preferable.

The substrate position detection apparatus according to an embodiment of the present invention is not necessarily arranged above the semiconductor device fabrication apparatus in which a wafer subject to the position detection is housed, but may be arranged in an appropriate place so that an image of the edge of the wafer and its surrounding area are taken. In addition, the opening of the chassis 102 and the window 102a that covers the opening may be provided in an appropriate portion except for the bottom portion of the chassis 102, depending on a configuration of the apparatus in which the wafer subject to the position detection is housed, as long as an image of the edge of the wafer and its surrounding area can be taken by the camera 104 through the opening of the chassis 102. Moreover, the chassis 102 is not always necessary. In this case, the camera 104, the panel 106, and the light source 108 may be attached to the semiconductor device fabrication apparatus so that an image of the edge of the wafer and its surrounding area are taken by the camera 104.

In addition, the substrate position detection apparatus according to an embodiment of the present invention is applicable to various semiconductor device fabrication apparatuses including an etching apparatus and a thermal processing apparatus, being not limited to the film deposition apparatus. Moreover, the substrate position detection apparatus and the substrate position detection method using the same may detect a position of not only a bare wafer but a wafer in which a circuit has been made through various processes. Incidentally, a susceptor of the semiconductor device fabrication apparatus may be made of quartz, metal or the like, rather than carbon or silicon carbide. Even when made of such materials, it is possible to accurately detect the wafer position. This is because while the wafer W placed on the susceptor is illuminated by the panel 106 so that the wafer W appears uniformly bright, a relatively strong contrast is obtained between the wafer W and the susceptor due to surface differences between the wafer W and the susceptor.

Furthermore, the substrate position detection apparatus according to an embodiment of the present invention may be used to detect a position of a flat panel display (FPD) substrate in an FPD fabrication apparatus.

While various modification examples are explained, it is apparent to a person having ordinary skill in the art that these modifications are variously combined and applied to the above embodiments.

What is claimed is:

1. A substrate position detection apparatus, comprising:
an imaging portion configured to take an image of a substrate subject to a position detection;
a panel member provided between the imaging portion and the substrate and including a first opening that ensures a field of view for the imaging portion with respect to the substrate, the panel member having a light scattering property;
a first illuminating portion configured to illuminate the panel member; and
a processing portion capable of determining a position of the substrate in accordance with the image taken through the first opening by the imaging portion.

2. The substrate position detection apparatus of claim 1, wherein the first illuminating portion illuminates a first surface of the panel member, the first surface facing the substrate.

3. The substrate position detection apparatus of claim 1, wherein the first illuminating portion illuminates a second surface of the panel member, the second surface facing the imaging portion.

4. The substrate position detection apparatus of claim 3, further comprising a second illuminating portion configured to illuminate the substrate.

5. The substrate position detection apparatus of claim 2, wherein the first illuminating portion configured to illuminate the first surface of the panel member may swivel in order to illuminate the substrate.

6. The substrate position detection apparatus of claim 1, wherein the panel member is made of a resin including light scattering particles.

7. The substrate position detection apparatus of claim 1, wherein the panel member is made of a transparent resin plate on which a pigment is painted.

8. The substrate position detection apparatus of claim 1, wherein at least one surface of a first surface and a second surface of the panel member is roughened.

9. The substrate position detection apparatus of claim 1, further comprising a chassis in which the imaging portion is housed, the chassis including
an opening facing toward the substrate subject to the position detection;
an inlet port from which gas is introduced to the chassis, and
an evacuation port from which the gas introduced from the inlet port flows out from the chassis; and
wherein the panel member is provided between the opening and the imaging portion in the chassis, and
wherein the panel member further includes a second opening through which the gas may flow.

10. The substrate position detection apparatus of claim 1, further comprising:
a detection portion provided in a rotational driving mechanism for rotating a susceptor on which the substrate subject to the position detection is placed, the detection portion detecting a position detection mark provided in the susceptor, and
wherein the processing portion detects whether the position detection mark is within a predetermined range from the image taken by the imaging portion.

11. The substrate position detection apparatus of claim 10, wherein the detection portion includes
a stator piece provided in the rotational driving mechanism; and
a rotating piece that is provided in a rotation portion of the rotational driving mechanism and cooperates with the stator piece.

12. A substrate position detection method comprising steps of:
placing a substrate subject to a position detection in a substrate receiving portion of a susceptor;
illuminating a panel member including a first opening and having a light scattering property;
taking an image of an area including the substrate and the substrate receiving portion through the first opening;
estimating a position of the substrate receiving portion in accordance with the image of the area;
estimating a position of the substrate in accordance with the image of the area; and
determining whether the substrate is in a predetermined position from the positions of the substrate and the substrate receiving portion.

13. The substrate position detection method of claim 12, wherein the step of estimating the position of the substrate receiving portion includes a step of detecting a position detection mark provided in the susceptor.

14. The substrate position detection method of claim 12, wherein the step of estimating the position of the substrate includes a step of recognizing an edge portion of the substrate placed in the substrate receiving portion.

15. The substrate position detection method of claim 13, wherein the step of estimating the position of the substrate receiving portion includes steps of:
detecting whether the position detection mark is within a predetermined range, in accordance with the image;
adjusting a position of the susceptor so that the position detection mark falls within the predetermined range, in accordance with a detection result obtained by a detection portion provided in a rotational driving mechanism for rotating the susceptor, when it is determined in the step of detecting that the position detection mark is not within the predetermined range; and
detecting the position detection mark within the predetermined range, in order to adjust the susceptor so that the position detection mark is positioned in a predetermined position, in accordance with a detection result of detecting the position detection mark within the predetermined range.

16. The substrate position detection method of claim 15, wherein the detection portion includes
a stator piece provided in the rotational driving mechanism; and
a rotating piece that is provided in a rotation portion of the rotational driving mechanism and cooperates with the stator piece.

17. A film deposition apparatus for depositing a film on a substrate by carrying out a cycle of alternately supplying at least two kinds of reaction gases that react with each other to the substrate to produce a layer of a reaction product in a chamber, the film deposition apparatus comprising:
a susceptor rotatably provided in the chamber;
a substrate receiving portion that is provided in one surface of the susceptor and the substrate is placed in;
a substrate position detection apparatus of claim 1 for detecting a position of the substrate placed in the substrate receiving portion;
a first reaction gas supplying portion configured to supply a first reaction gas to the one surface;
a second reaction gas supplying portion configured to supply a second reaction gas to the one surface, the second reaction gas supplying portion being separated from the first reaction gas supplying portion along a rotation direction of the susceptor;
a separation area located along the rotation direction between a first process area in which the first reaction gas is supplied and a second process area in which the second reaction gas is supplied;
a center area that is located substantially in a center portion of the chamber in order to separate the first process area and the second process area, and has an ejection hole that ejects a first separation gas along the one surface; and
an evacuation opening provided in the chamber in order to evacuate the chamber;
wherein the separation area includes a separation gas supplying portion that supplies a second separation gas, and a ceiling surface that creates in relation to the one surface of the susceptor a thin space in which the second separation gas may flow from the separation area to the process area side in relation to the rotation direction.

18. A film deposition method for depositing a film on a substrate, using the film deposition apparatus recited in claim 17, the film deposition method comprising steps of:
placing the substrate on the substrate receiving portion provided in one surface of the susceptor rotatably provided in the chamber;
illuminating the panel member including the first opening and having a light scattering property;
taking an image of an area including the substrate and the substrate receiving portion through the first opening;
estimating a position of the substrate receiving portion in accordance with the image of the area;
estimating a position of the substrate in accordance with the image of the area; and
determining whether the substrate is in a predetermined position from the positions of the substrate and the substrate receiving portion;
rotating the susceptor on which the substrate is placed, when it is determined that the substrate is in the predetermined position in the step of determining;
supplying the first reaction gas from the first reaction gas supplying portion to the susceptor;
supplying the second reaction gas from the second reaction gas supplying portion to the susceptor, the second reaction gas supplying portion being separated from the first reaction gas supplying portion along the rotation direction of the susceptor;
supplying the first separation gas from the separation gas supplying portion provided in the separation area located between the first process area in which the first reaction gas is supplied from the first reaction gas supplying portion and the second process area in which the second reaction gas is supplied from the second reaction gas supplying portion, in order to flow the first separation gas from the separation area to the process area relative to the rotation direction of the susceptor in the thin space created between the ceiling surface of the separation area and the susceptor;
supplying the second separation gas from the ejection hole formed in the center area located in the center portion of the chamber; and
evacuating the chamber.

19. A computer readable storage medium storing a program for causing the substrate position detection apparatus of claim 1 to perform a substrate position detection method comprising steps of:
placing the substrate subject to the position detection in the substrate receiving portion of the susceptor;
illuminating the panel member provided above the substrate and including the first opening, the panel member having a light scattering property;
taking an image of an area including the substrate and the substrate receiving portion through the first opening;
estimating a position of the substrate receiving portion in accordance with the image of the area;
estimating a position of the substrate in accordance with the image of the area; and
determining whether the substrate is in a predetermined position from the positions of the substrate and the substrate receiving portion.

20. A computer readable storage medium storing a program for causing the film deposition apparatus of claim 17 to perform a film deposition method comprising steps of:
placing the substrate on the substrate receiving portion provided in one surface of the susceptor rotatably provided in the chamber;
illuminating the panel member provided above the substrate and including the first opening, the panel member having a light scattering property;
taking an image of an area including the substrate and the substrate receiving portion through the first opening;
estimating a position of the substrate receiving portion in accordance with the image of the area;
estimating a position of the substrate in accordance with the image of the area; and
determining whether the substrate is in predetermined position from the positions of the substrate and the substrate receiving portion;
rotating the susceptor on which the substrate is placed, when it is determined that the substrate is in the predetermined position in the step of determining;
supplying the first reaction gas from the first reaction gas supplying portion to the susceptor;
supplying the second reaction gas from the second reaction gas supplying portion to the susceptor, the second reaction gas supplying portion being separated from the first reaction gas supplying portion along the rotation direction of the susceptor;
supplying the first separation gas from the separation gas supplying portion provided in the separation area located between the first process area in which the first reaction gas is supplied from the first reaction gas supplying portion and the second process area in which the second reaction gas is supplied from the second reaction gas supplying portion, in order to flow the first separation gas from the separation area to the process area relative to the rotation direction of the susceptor in the thin space created between the ceiling surface of the separation area and the susceptor;
supplying the second separation gas from the ejection hole formed in the center area located in the center portion of the chamber; and
evacuating the chamber.
